(19) United States
(12) Patent Application Publication
(10) Pub. No.: US 2023/0252672 A1
(43) Pub. Date: Aug. 10, 2023

(54) METHODS AND APPARATUS FOR USE IN THE SPATIAL REGISTRATION OF OBJECTS

(71) Applicant: University of Strathclyde, Glasgow (GB)

(72) Inventor: Michael Strain, Glasgow (GB)

(21) Appl. No.: 18/014,609

(22) PCT Filed: Jul. 6, 2021
(86) PCT No.: PCT/GB2021/051722

§ 371 Date: Jan. 5, 2023

(30) Foreign Application Priority Data
Jul. 6, 2020 (GB) 2010350.3

(51) Int. Cl. G06T 7/73; G06T 7/33; G03F 9/00

(52) U.S. Cl. CPC G06T 7/73; G06T 7/33; G03F 9/7088; G06T 2207/30148; G06T 2207/30204

(57) ABSTRACT

A method for use in the spatial registration of first and second objects comprises fixing the first and second objects to the same motion control stage in an unknown spatial relationship, using an imaging system to acquire an image of the first object, determining a position and orientation of the first object in a frame of reference of the motion control stage based at least in part on the acquired image of the first object, using the imaging system to acquire an image of the second object, and determining a position and orientation of the second object in the frame of reference of the motion control stage based at least in part on the acquired image of the second object. The method may be used in the spatial registration of first and second objects and, in particular though not exclusively, for use in the spatial registration of optical or electronic components relative to one another, or for use in the alignment of a first object such as an optical or electronic component relative to a second object such as a feature, a structure, a target area or a target region defined on a substrate or a wafer.

### FIELD

The present disclosure relates to methods and apparatus for use in the spatial registration of first and second objects and, in particular though not exclusively, for use in the spatial registration of optical or electronic components relative to one another, or for use in the alignment of a first object such as an optical or electronic component relative to a second object such as a feature, a structure, a target area or a target region defined on a substrate or a wafer.

### BACKGROUND

It is known to acquire an image of a first object such as a substrate or a PCB in a field of view of a vision system, and to analyse the image of the object to determine the position and orientation of the object in the frame of reference of the vision system. It is also known to place a second object such as an optical or electronic component at a desired position and with a desired orientation relative to the first object.

Furthermore, it is known to align a first object such as lithographic mask and a second object such as a wafer relative to one another in a field of view of a vision system.

However, such known alignment techniques may not provide sufficient alignment precision for some technical applications e.g. when aligning objects such as optical or electronic components relative to one another, or when aligning a first object such as an optical or electronic component relative to a second object such as a feature or a structure or a target area or target region defined on a substrate or a wafer.

### SUMMARY

According to an aspect of the present disclosure there is provided a method for use in the spatial registration of first and second objects, the method comprising:

fixing the first and second objects to the same motion control stage in an unknown spatial relationship;

using an imaging system to acquire an image of the first object or to acquire an image of a first marker provided with the first object, wherein the first marker and the first object have a known spatial relationship;

determining a position and orientation of the first object in a frame of reference of the motion control stage based at least in part on the acquired image of the first object or based at least in part on the acquired image of the first marker and the known spatial relationship between the first marker and the first object;

using the imaging system to acquire an image of the second object or to acquire an image of a second marker provided with the second object, wherein the second marker and the second object have a known spatial relationship; and

determining a position and orientation of the second object in the frame of reference of the motion control stage based at least in part on the acquired image of the second object or based at least in part on the acquired image of the second marker and the known spatial relationship between the second marker and the second object.

The method may comprise determining a spatial relationship between the first and second objects in the frame of reference of the motion control stage based on the determined position and orientation of the first object in the frame of reference of the motion control stage and the determined position and orientation of the second object in the frame of reference of the motion control stage.

Such a method may enable the position and orientation of the first object and the position and orientation of the second object to be known in the frame of reference of the motion control stage to within a relative positional resolution or accuracy of the motion control stage and to within a relative orientational resolution or accuracy of the motion control stage. Such a method does not rely on an absolute positional resolution or accuracy of the motion control stage or an absolute orientational resolution or accuracy of the motion control stage. For state-of-the-art motion control stages, such a method may enable the spatial registration of the first and second objects to a resolution or accuracy of less than 1 μm, less than 100 nm, less than 10 nm, or of the order of 1 nm. Such a method may enable the spatial registration of the first and second objects where the first and second objects have a size or scale of the order of 10 mm, less than 1 mm, less than 100 μm, less than 10 μm, less than 1 μm or in the range of 100 nm to 1 μm.

The first object may comprise a component such as an optical or an electronic component.

The second object may comprise a component such as an optical or an electronic component.

Such a method may enable the spatial registration of components relative to one another.

The first object may comprise a portion, piece or chip of material. The material may be a crystalline material. The material may comprise, or be formed from, a thin film or a 2D material such as graphene, hexa-boron nitride or the like.

The second object may comprise a portion, piece or chip of material. The material may be a crystalline material. The material may comprise, or be formed from, a thin film or a 2D material such as graphene, hexa-boron nitride or the like.

Such a method may enable the spatial registration of portions, pieces or chips of material relative to one another.

The first object may be detachably attached to the motion control stage.

The first object may be detachably attached to a first substrate or wafer, wherein the first substrate or wafer is fixed to the motion control stage.

The second object may comprise a feature, a structure, a target area, a target region, or a component defined on a second substrate or wafer, wherein the second substrate or wafer is fixed to the motion control stage.

Such a method may enable the alignment of a first component relative to a feature, a structure, a target area, a target region, or a second component defined on a substrate or a wafer.

The first and second objects may both be located in a field of view of the imaging system at the same time.

The first and second objects may both be located in a field of view of the imaging system at different times. The method may comprise using the motion control stage to move the first object into the field of view of the imaging system at a first time and using the motion control stage to move the second object into the field of view of the imaging system at a second time different to the first time.

The first and second markers may both be located in a field of view of the imaging system at the same time.

The first and second markers may both be located in a field of view of the imaging system at different times. The method may comprise using the motion control stage to move the first marker into the field of view of the imaging system at a first time and using the motion control stage to move the second marker into the field of view of the imaging system at a second time different to the first time.

The method may comprise spatially registering the first and second objects based on the determined spatial relationship between the first and second objects in the frame of reference of the motion control stage.

The method may comprise detaching the first object from the motion control stage.

The method may comprise detaching the first object from the first substrate.

The method may comprise holding the first object.

The method may comprise moving the first object and the motion control stage apart.

The method may comprise holding the first object spaced apart from the motion control stage and the second object to permit the motion control stage to move the second object relative to the first object.

The method may comprise aligning a tool, head, stamp, probe or holder with respect to the first object.

Aligning the tool, head, stamp, probe or holder with respect to the first object may comprise aligning the tool, head, stamp, probe or holder with respect to the first object based on the determined position and orientation of the first object in the frame of reference of the motion control stage and a known position and orientation of the tool, head, stamp, probe or holder relative to the motion control stage.

The method may comprise engaging the first object with the tool, head, stamp, probe or holder.

The method may comprise using the tool, head, stamp, probe or holder to hold the first object.

The method may comprise using the tool, head, stamp, probe or holder to detach the first object from the motion control stage.

The method may comprise moving the motion control stage away from the first object.

The method may comprise using the tool, head, stamp, probe or holder to move the first object away from the motion control stage.

The method may comprise using the motion control stage to move the second object relative to the first object based on the determined spatial relationship between the first and second objects in the frame of reference of the motion control stage until the first and second objects are in alignment.

The method may comprise bringing the first and second objects together until the first and second objects are aligned and in engagement.

The method may comprise:

using a tool, head, stamp, probe or holder to hold the first object until the first and second objects are aligned and in engagement; and then

using the tool, head, stamp, probe or holder to release the first object to permit attachment of the first and second objects.

The method may comprise using the motion control stage to move the second object towards the first object until the first and second objects are aligned and in engagement.

The method may comprise using the tool, head, stamp, probe or holder to move the first object towards the second object until the first and second objects are aligned and in engagement.

The method may comprise attaching the first and second objects while the first and second objects are aligned.

Such a method may be used in the micro-assembly of the first and second objects, for example for transfer printing the first object onto the second object.

Attaching the first and second objects together may comprise using a differential adhesion method and/or capillary bonding to attach the first and second objects together.

Attaching the first and second objects together may comprise bonding the first and second objects together using an intermediate adhesive material or agent such as an intermediate adhesion layer.

Attaching the first and second objects together may comprise soldering the first and second objects together.

The method may comprise flipping the first object over before attaching the first and second objects together.

One of the first and second objects may comprise a lithographic mask and the other of the first and second objects may comprise a work-piece e.g. a substrate or a wafer. The work-piece may comprise photoresist to be exposed to visible and/or UV light through the lithographic mask.

The method may comprise:

(i) determining a degree of similarity between the acquired image of the first object and a fixed virtual image of the first object, which fixed virtual image of the first object has the same size and shape as the first object and a fixed spatial relationship with respect to the FOV of the imaging system, and responsive to determining that the degree of similarity between the acquired image of the first object and the fixed virtual image of the first object does not comply with a predetermined criterion, translating and/or rotating the motion control stage with respect to the imaging system while maintaining the first object in the FOV of the imaging system until the degree of similarity between the acquired image of the first object and the fixed virtual image of the first object complies with the predetermined criterion;

(ii) measuring a corresponding relative position and orientation of the motion control stage when the degree of similarity between the acquired image of the first object and the fixed virtual image of the first object complies with the predetermined criterion; and

(iii) determining the position and orientation of the first object in the frame of reference of the motion control stage based on the measured relative position and orientation of the motion control stage when the degree of similarity between the acquired image of the first object and the fixed virtual image of the first object complies with the predetermined criterion.

The degree of similarity between the acquired image of the first object and the fixed virtual image of the first object may comply with the predetermined criterion when the degree of similarity is greater than a predetermined threshold value.

The degree of similarity between the acquired image of the first object and the fixed virtual image of the first object may comply with the predetermined criterion when the degree of similarity has a maximum value.

Determining the degree of similarity between the acquired image of the first object and the fixed virtual image of the first object may comprise evaluating a cross-correlation value between the acquired image of the first object and the fixed virtual image of the first object. The degree of similarity between the acquired image of the first object and the fixed virtual image of the first object may comply with the predetermined criterion when the cross-correlation value is greater than a predetermined threshold value or has a maximum value.

Determining the degree of similarity between the acquired image of the first object and the fixed virtual image of the first object by evaluating a cross-correlation value may allow the position and orientation of the first object to be determined in the frame of reference of the motion control stage with a greater degree of accuracy than prior art edge-detection methods.

The method may comprise:

(i) determining a degree of similarity between the acquired image of the second object and a fixed virtual image of the second object, which fixed virtual image of the second object has the same size and shape as the second object and a fixed spatial relationship with respect to the FOV of the imaging system, and responsive to determining that the degree of similarity between the acquired image of the second object and the fixed virtual image of the second object does not comply with a predetermined criterion, translating and/or rotating the motion control stage with respect to the imaging system while maintaining the second object in the FOV of the imaging system until the degree of similarity between the acquired image of the second object and the fixed virtual image of the second object complies with the predetermined criterion;

(ii) measuring a corresponding relative position and orientation of the motion control stage when the degree of similarity between the acquired image of the second object and the fixed virtual image of the second object complies with the predetermined criterion; and

(iii) determining the position and orientation of the second object in the frame of reference of the motion control stage based on the measured relative position and orientation of the motion control stage when the degree of similarity between the acquired image of the second object and the fixed virtual image of the second object complies with the predetermined criterion.

The degree of similarity between the acquired image of the second object and the fixed virtual image of the second object may comply with the predetermined criterion when the degree of similarity is greater than a predetermined threshold value.

The degree of similarity between the acquired image of the second object and the fixed virtual image of the second object may comply with the predetermined criterion when the degree of similarity has a maximum value.

Determining the degree of similarity between the acquired image of the second object and the fixed virtual image of the second object may comprise evaluating a cross-correlation value between the acquired image of the second object and the fixed virtual image of the second object. The degree of similarity between the acquired image of the second object and the fixed virtual image of the second object may comply with the predetermined criterion when the cross-correlation value is greater than a predetermined threshold value or has a maximum value.

Determining the degree of similarity between the acquired image of the second object and the fixed virtual image of the second object by evaluating a cross-correlation value may allow the position and orientation of the second object to be determined in the frame of reference of the motion control stage with a greater degree of accuracy than prior art edge-detection methods.

The method may comprise:

(i) measuring a relative position and orientation of the motion control stage corresponding to an acquired image of the first object;

(ii) determining a degree of similarity between the acquired image of the first object and a virtual image of the first object, which virtual image of the first object has the same size and shape as the first object, and responsive to determining that the degree of similarity between the acquired image of the first object and the virtual image of the first object does not comply with a predetermined criterion, translating and/or rotating the virtual image of the first object with respect to the FOV of the imaging system until the degree of similarity between the acquired image of the first object and the virtual image of the first object complies with the predetermined criterion; and

(iii) determining the position and orientation of the first object in the frame of reference of the motion control stage based on the measured relative position and orientation of the motion control stage corresponding to the acquired image of the first object and the relative position and orientation of the virtual image of the first object with respect to the FOV of the imaging system when the degree of similarity between the virtual image of the first object and the acquired image of the first object complies with the predetermined criterion.

The degree of similarity between the acquired image of the first object and the virtual image of the first object may comply with the predetermined criterion when the degree of similarity is greater than a predetermined threshold value.

The degree of similarity between the acquired image of the first object and the virtual image of the first object may comply with the predetermined criterion when the degree of similarity has a maximum value.

Determining the degree of similarity between the acquired image of the first object and the virtual image of the first object may comprise evaluating a cross-correlation value between the acquired image of the first object and the virtual image of the first object. The degree of similarity between the acquired image of the first object and the virtual image of the first object may comply with the predetermined criterion when the cross-correlation value is greater than a predetermined threshold value or has a maximum value.

Determining the degree of similarity between the acquired image of the first object and the virtual image of the first object by evaluating a cross-correlation value may allow the position and orientation of the first object to be determined in the frame of reference of the motion control stage with a greater degree of accuracy than prior art edge-detection methods.

The method may comprise:

(i) measuring a relative position and orientation of the motion control stage corresponding to an acquired image of the second object;

(ii) determining a degree of similarity between the acquired image of the second object and a virtual image of the second object, which virtual image of the second object has the same size and shape as the second object, and responsive to determining that the degree of similarity between the acquired image of the second object and the virtual image of the second object does not comply with a predetermined criterion, translating and/or rotating the virtual image of the second object with respect to the FOV of the imaging system until the degree of similarity between the acquired image of the second object and the virtual image of the second object complies with the predetermined criterion; and

(iii) determining the position and orientation of the second object in the frame of reference of the motion control stage based on the measured relative position and orientation of the motion control stage corresponding to the acquired image of the second object and the relative position and orientation of the virtual image of the second object with respect to the FOV of the imaging system when the degree of similarity between the virtual image of the second object and the acquired image of the second object complies with the predetermined criterion.

The degree of similarity between the acquired image of the second object and the virtual image of the second object may comply with the predetermined criterion when the degree of similarity is greater than a predetermined threshold value.

The degree of similarity between the acquired image of the second object and the virtual image of the second object may comply with the predetermined criterion when the degree of similarity has a maximum value.

Determining the degree of similarity between the acquired image of the second object and the virtual image of the second object may comprise evaluating a cross-correlation value between the acquired image of the second object and the virtual image of the second object. The degree of similarity between the acquired image of the second object and the virtual image of the second object may comply with the predetermined criterion when the cross-correlation value is greater than a predetermined threshold value or has a maximum value.

Determining the degree of similarity between the acquired image of the second object and the virtual image of the second object by evaluating a cross-correlation value may allow the position and orientation of the second object to be determined in the frame of reference of the motion control stage with a greater degree of accuracy than prior art edge-detection methods.

The method may comprise compensating the determined spatial relationship between the first and second objects in the frame of reference of the motion control stage for any misalignment between a z-axis of the motion control stage and an optical axis of the imaging system, wherein the z-axis of the motion control stage is normal to a surface of the motion control stage to which the first and second objects are attached.

The first object may define the first marker.

The first object may comprise part of a first substrate or the first object may be defined by, or on, a first substrate.

The first substrate may define the first marker.

The method may comprise determining the position and orientation of the first marker in the frame of reference of the motion control stage based at least in part on the acquired image of the first marker and using the determined position and orientation of the first marker in the frame of reference of the motion control stage and the known spatial relationship between the first marker and the first object to determine the position and orientation of the first object in the frame of reference of the motion control stage.

The first marker may be rotationally asymmetric.

The first marker may be aperiodic in one or two dimensions.

The first marker may define a plurality of features. At least one of the features of the first marker may have a different size and/or shape to the other features of the first marker. Each one of the features of the first marker may be different in size and/or shape to each of the other features of the first marker. The separation of two adjacent features of the first marker may be different to the separation of any two other adjacent features of the first marker in one or two dimensions. The separation of any two adjacent features of the first marker may be different to the separation of any two other adjacent features of the first marker in one or two dimensions.

The first marker may comprise, or take the form of, a grid which is rotationally asymmetric.

The first marker may comprise, or take the form of, a grid which is aperiodic in one or two dimensions.

The second object may define the second marker.

The second object may comprise part of a second substrate or the second object may be defined by, or on, a second substrate.

The second object may comprise a target area or a target region defined by, or on, the second substrate.

The target area or a target region may coincide with a feature, structure or component attached to or defined by, or on, the second substrate.

The second substrate may define the second marker.

The second substrate may have an unknown spatial relationship relative to the first substrate.

The method may comprise determining the position and orientation of the second marker in the frame of reference of the motion control stage based at least in part on the acquired image of the second marker and using the determined position and orientation of the second marker in the frame of reference of the motion control stage and the known spatial relationship between the second marker and the second object to determine the position and orientation of the second object in the frame of reference of the motion control stage.

The second marker may be rotationally asymmetric.

The second marker may be aperiodic in one or two dimensions.

The second marker may define a plurality of features. At least one of the features of the second marker may have a different size and/or shape to the other features of the second marker. Each one of the features of the second marker may be different in size and/or shape to each of the other features of the second marker. The separation of two adjacent features of the second marker may be different to the separation of any two other adjacent features of the second marker in one or two dimensions. The separation of any two adjacent features of the second marker may be different to the separation of any two other adjacent features of the second marker in one or two dimensions.

The second marker may comprise, or take the form of, a grid which is rotationally asymmetric.

The second marker may comprise, or take the form of, a grid which is aperiodic in one or two dimensions.

The method may comprise:

(i) determining a degree of similarity between the acquired image of the first marker and a fixed virtual image of the first marker, which fixed virtual image of the first marker has the same size and shape as the first marker and a fixed spatial relationship with respect to the FOV of the imaging system, and responsive to determining that the degree of similarity between the acquired image of the first marker and the fixed virtual image of the first marker does not comply with a predetermined criterion, translating and/or rotating the motion control stage with respect to the imaging system while maintaining the first marker in the FOV of the imaging system until the degree of similarity between the acquired image of the first marker and the fixed virtual image of the first marker complies with the predetermined criterion;

(ii) measuring a corresponding relative position and orientation of the motion control stage when the degree of similarity between the acquired image of the first marker and the fixed virtual image of the first marker complies with the predetermined criterion; and

(iii) determining the position and orientation of the first marker in the frame of reference of the motion control stage based on the measured relative position and orientation of the motion control stage when the degree of similarity between the acquired image of the first marker and the fixed virtual image of the first marker complies with the predetermined criterion.

The degree of similarity between the acquired image of the first marker and the fixed virtual image of the first marker may comply with the predetermined criterion when the degree of similarity is greater than a predetermined threshold value.

The degree of similarity between the acquired image of the first marker and the fixed virtual image of the first marker may comply with the predetermined criterion when the degree of similarity has a maximum value.

Determining the degree of similarity between the acquired image of the first marker and the fixed virtual image of the first marker may comprise evaluating a cross-correlation value between the acquired image of the first marker and the fixed virtual image of the first marker. The degree of similarity between the acquired image of the first marker and the fixed virtual image of the first marker may comply with the predetermined criterion when the cross-correlation value is greater than a predetermined threshold value or has a maximum value.

Determining the degree of similarity between the acquired image of the first marker and the virtual image of the first marker by evaluating a cross-correlation value may allow the position and orientation of the first marker to be determined in the frame of reference of the motion control stage with a greater degree of accuracy than prior art edge-detection methods.

The method may comprise:

(i) determining a degree of similarity between the acquired image of the second marker and a fixed virtual image of the second marker, which fixed virtual image of the second marker has the same size and shape as the second marker and a fixed spatial relationship with respect to the FOV of the imaging system, and responsive to determining that the degree of similarity between the acquired image of the second marker and the fixed virtual image of the second marker does not comply with a predetermined criterion, translating and/or rotating the motion control stage with respect to the imaging system while maintaining the second marker in the FOV of the imaging system until the degree of similarity between the acquired image of the second marker and the fixed virtual image of the second marker complies with the predetermined criterion;

(ii) measuring a corresponding relative position and orientation of the motion control stage when the degree of similarity between the acquired image of the second marker and the fixed virtual image of the second marker complies with the predetermined criterion; and

(iii) determining the position and orientation of the second marker in the frame of reference of the motion control stage based on the measured relative position and orientation of the motion control stage when the degree of similarity between the acquired image of the second marker and the fixed virtual image of the second marker complies with the predetermined criterion.

The degree of similarity between the acquired image of the second marker and the fixed virtual image of the second marker may comply with the predetermined criterion when the degree of similarity is greater than a predetermined threshold value.

The degree of similarity between the acquired image of the second marker and the fixed virtual image of the second marker may comply with the predetermined criterion when the degree of similarity has a maximum value.

Determining the degree of similarity between the acquired image of the second marker and the fixed virtual image of the second marker may comprise evaluating a cross-correlation value between the acquired image of the second marker and the fixed virtual image of the second marker. The degree of similarity between the acquired image of the second marker and the fixed virtual image of the second marker may comply with the predetermined criterion when the cross-correlation value is greater than a predetermined threshold value or has a maximum value.

Determining the degree of similarity between the acquired image of the second marker and the virtual image of the second marker by evaluating a cross-correlation value may allow the position and orientation of the second marker to be determined in the frame of reference of the motion control stage with a greater degree of accuracy than prior art edge-detection methods.

The method may comprise:

(i) measuring a relative position and orientation of the motion control stage corresponding to an acquired image of the first marker;

(ii) determining a degree of similarity between the acquired image of the first marker and a virtual image of the first marker, which virtual image of the first marker has the same size and shape as the first marker, and responsive to determining that the degree of similarity between the acquired image of the first marker and the virtual image of the first marker does not comply with a predetermined criterion, translating and/or rotating the virtual image of the first marker with respect to the FOV of the imaging system until the degree of similarity between the acquired image of the first marker and the virtual image of the first marker complies with the predetermined criterion; and

(iii) determining the position and orientation of the first marker in the frame of reference of the motion control stage based on the measured relative position and orientation of the motion control stage corresponding to the acquired image of the first marker and the relative position and orientation of the virtual image of the first marker with respect to the FOV of the imaging system when the degree of similarity between the virtual image of the first marker and the acquired image of the first marker complies with the predetermined criterion.

The degree of similarity between the acquired image of the first marker and the virtual image of the first marker may comply with the predetermined criterion when the degree of similarity is greater than a predetermined threshold value.

The degree of similarity between the acquired image of the first marker and the virtual image of the first marker may comply with the predetermined criterion when the degree of similarity has a maximum value.

Determining the degree of similarity between the acquired image of the first marker and the virtual image of the first marker may comprise evaluating a cross-correlation value between the acquired image of the first marker and the virtual image of the first marker. The degree of similarity between the acquired image of the first marker and the virtual image of the first marker may comply with the predetermined criterion when the cross-correlation value is greater than a predetermined threshold value or has a maximum value.

Determining the degree of similarity between the acquired image of the first marker and the virtual image of the first marker by evaluating a cross-correlation value may allow the position and orientation of the first marker to be determined in the frame of reference of the motion control stage with a greater degree of accuracy than prior art edge-detection methods.

The method may comprise:

(i) measuring a relative position and orientation of the motion control stage corresponding to an acquired image of the second marker;

(ii) determining a degree of similarity between the acquired image of the second marker and a virtual image of the second marker, which virtual image of the second marker has the same size and shape as the second marker, and responsive to determining that the degree of similarity between the acquired image of the second marker and the virtual image of the second marker does not comply with a predetermined criterion, translating and/or rotating the virtual image of the second marker with respect to the FOV of the imaging system until the degree of similarity between the acquired image of the second marker and the virtual image of the second marker complies with the predetermined criterion; and

(iii) determining the position and orientation of the second marker in the frame of reference of the motion control stage based on the measured relative position and orientation of the motion control stage corresponding to the acquired image of the second marker and the relative position and orientation of the virtual image of the second marker with respect to the FOV of the imaging system when the degree of similarity between the virtual image of the second marker and the acquired image of the second marker complies with the predetermined criterion.

The degree of similarity between the acquired image of the second marker and the virtual image of the second marker may comply with the predetermined criterion when the degree of similarity is greater than a predetermined threshold value.

The degree of similarity between the acquired image of the second marker and the virtual image of the second marker may comply with the predetermined criterion when the degree of similarity has a maximum value.

Determining the degree of similarity between the acquired image of the second marker and the virtual image of the second marker may comprise evaluating a cross-correlation value between the acquired image of the second marker and the virtual image of the second marker. The degree of similarity between the acquired image of the second marker and the virtual image of the second marker may comply with the predetermined criterion when the cross-correlation value is greater than a predetermined threshold value or has a maximum value.

Determining the degree of similarity between the acquired image of the second marker and the virtual image of the second marker by evaluating a cross-correlation value may allow the position and orientation of the second marker to be determined in the frame of reference of the motion control stage with a greater degree of accuracy than prior art edge-detection methods.

The first substrate may define a further first marker.

The first object may define a further first marker.

The method may comprise:

(i) measuring a relative position and orientation of the motion control stage corresponding to the acquired image of the first marker;

(ii) determining a degree of similarity between the acquired image of the first marker and a virtual image of the first marker, which virtual image of the first marker has the same size and shape as the first marker, and responsive to determining that the degree of similarity between the acquired image of the first marker and the virtual image of the first marker does not comply with a predetermined criterion, translating the virtual image of the first marker with respect to a FOV of the imaging system until the degree of similarity between the acquired image of the first marker and the virtual image of the first marker complies with the predetermined criterion;

(iii) translating the motion control stage along a linear translation axis of the motion control stage by a distance equal to a known separation between the first marker and the further first marker which is also provided with the first object so that the further first marker is in the FOV of the imaging system;

(iv) using the imaging system to acquire an image of the further first marker;

(v) measuring a relative position and orientation of the motion control stage corresponding to an acquired image of the further first marker;

(vi) determining a degree of similarity between the acquired image of the further first marker and a virtual image of the further first marker, which virtual image of the further first marker has the same size and shape as the further first marker, and translating the virtual image of the further first marker with respect to the FOV of the imaging system until the degree of similarity between the acquired image of the further first marker and the virtual image of the further first marker complies with a predetermined criterion; and

(vii) determining the position and orientation of the first marker in the frame of reference of the motion control stage based on:
(a) the measured relative position of the motion control stage corresponding to the acquired image of the first marker;
(b) the relative position of the virtual image of the first marker with respect to the FOV of the imaging system when the degree of similarity between the virtual image of the first marker and the acquired image of the first marker complies with the predetermined criterion;
(c) the measured relative position of the motion control stage corresponding to the acquired image of the further first marker; and
(d) the relative position of the virtual image of the further first marker with respect to the FOV of the imaging system when the degree of similarity between the virtual image of the further first marker and the acquired image of the further first marker complies with the predetermined criterion.

Use of a first marker and a further first marker on the first substrate or the first object in this way may allow the orientation of the first substrate or the first object to be determined in the frame of reference of the motion control stage to a greater precision than the use of just the first marker.

Determining the degree of similarity between the acquired image of the first marker and the virtual image of the first marker may comprise evaluating a cross-correlation value between the acquired image of the first marker and the virtual image of the first marker and wherein the degree of similarity between the acquired image of the first marker and the virtual image of the first marker complies with the predetermined criterion when the cross-correlation value is greater than a predetermined threshold value or has a maximum value.

Determining the degree of similarity between the acquired image of the further first marker and the virtual image of the further first marker may comprise evaluating a cross-correlation value between the acquired image of the further first marker and the virtual image of the further first marker and wherein the degree of similarity between the acquired image of the further first marker and the virtual image of the further first marker complies with the predetermined criterion when the cross-correlation value is greater than a predetermined threshold value or has a maximum value.

The second substrate may define a further second marker.

The second object may define a further second marker.

The method may comprise:

(i) measuring a relative position and orientation of the motion control stage corresponding to the acquired image of the second marker;

(ii) determining a degree of similarity between the acquired image of the second marker and a virtual image of the second marker, which virtual image of the second marker has the same size and shape as the second marker, and responsive to determining that the degree of similarity between the acquired image of the second marker and the virtual image of the second marker does not comply with a predetermined criterion, translating the virtual image of the second marker with respect to a FOV of the imaging system until the degree of similarity between the acquired image of the second marker and the virtual image of the second marker complies with the predetermined criterion;

(iii) translating the motion control stage along a linear translation axis of the motion control stage by a distance equal to a known separation between the second marker and the further second marker which is also provided with the second object so that the further second marker is in the FOV of the imaging system;

(iv) using the imaging system to acquire an image of the further second marker;

(v) measuring a relative position and orientation of the motion control stage corresponding to an acquired image of the further second marker;

(vi) determining a degree of similarity between the acquired image of the further second marker and a virtual image of the further second marker, which virtual image of the further second marker has the same size and shape as the further second marker, and translating the virtual image of the further second marker with respect to the FOV of the imaging system until the degree of similarity between the acquired image of the further second marker and the virtual image of the further second marker complies with a predetermined criterion; and

(vii) determining the position and orientation of the second marker in the frame of reference of the motion control stage based on:
(a) the measured relative position of the motion control stage corresponding to the acquired image of the second marker;
(b) the relative position of the virtual image of the second marker with respect to the FOV of the imaging system when the degree of similarity between the virtual image of the second marker and the acquired image of the second marker complies with the predetermined criterion;
(c) the measured relative position of the motion control stage corresponding to the acquired image of the further second marker; and
(d) the relative position of the virtual image of the further second marker with respect to the FOV of the imaging system when the degree of similarity between the virtual image of the further second marker and the acquired image of the further second marker complies with the predetermined criterion.

Use of a second marker and a further second marker on the second substrate or the second object in this way may allow the orientation of the second substrate or the second object to be determined in the frame of reference of the motion control stage to a greater precision than the use of just the second marker.

Determining the degree of similarity between the acquired image of the second marker and the virtual image of the second marker may comprise evaluating a cross-correlation value between the acquired image of the second marker and the virtual image of the second marker and wherein the degree of similarity between the acquired image of the second marker and the virtual image of the second marker complies with the predetermined criterion when the cross-correlation value is greater than a predetermined threshold value or has a maximum value; and

Determining the degree of similarity between the acquired image of the further second marker and the virtual image of the further second marker may comprise evaluating a cross-correlation value between the acquired image of the further second marker and the virtual image of the further second marker and wherein the degree of similarity between the acquired image of the further second marker and the virtual image of the further second marker complies with the predetermined criterion when the cross-correlation value is greater than a predetermined threshold value or has a maximum value.

The method may comprise spatially registering different first objects with the same second object.

The method may comprise spatially registering different first objects to different target areas on the same second substrate.

The method may comprise transferring different components defined on, or attached to, different first substrates to different target areas on the same second substrate.

The method may comprise spatially registering different first objects with different second objects.

The method may comprise spatially registering different first objects to different target areas on different second substrates.

The method may comprise transferring different components defined on, or attached to, different first substrates to different target areas on different second substrates.

The method may comprise compensating the determined spatial relationship between the target area and the component in the frame of reference of the motion control stage for any misalignment between a z-axis of the motion control stage and an optical axis of the imaging system, wherein the z-axis of the motion control stage is normal to a surface of the motion control stage to which the first and second substrates are attached.

The motion control stage may comprise a base and a table which is movable relative to the base.

The motion control stage may comprise one or more position sensors for measuring a position of the table relative to the base, and measuring the relative position of the motion control stage may comprise using the one or more position sensors to measure the position of the table of the motion control stage relative to the base of the motion control stage.

The motion control stage may comprise one or more orientation sensors for measuring an orientation of the table relative to the base, and measuring the relative orientation of the motion control stage may comprise using the one or more orientation sensors to measure the orientation of the table of the motion control stage relative to the base of the motion control stage.

According to an aspect of the present disclosure there is provided a method for use in the spatial registration of first and second objects, the second object being fixed or attached to a surface and the surface having one or more regions adjacent to the second object, which surface regions have a different reflectivity to the second object, and the method comprising:

locating the first object between a light source and the second object;

directing light from the light source onto the first object, the second object, and one or more of the surface regions of the surface adjacent to the second object;

using single-pixel detection to measure the optical power of at least a portion of the light that is reflected from the first and second objects and the one or more surface regions adjacent to the second object while the first and second objects are aligned relative to one another; and

aligning the first and second objects relative to one another until the measured optical power is maximised or minimised.

Such a method may enable the spatial registration of the first and second objects to a resolution or accuracy of less than 1 μm, less than 100 nm, less than 10 nm, or of the order of 1 nm. Such a method may enable the spatial registration of the first and second objects where the first and second objects have a size or scale of less than 1 μm, less than 100 nm, less than 10 nm, or of the order of 1 nm.

The first object may comprise a component such as an optical or an electronic component.

The second object may comprise a component such as an optical or an electronic component.

Such a method may enable the spatial registration of components relative to one another.

The first object may comprise a portion, piece or chip of material. The material may be a crystalline material. The material may comprise, or be formed from, a thin film or a 2D material such as graphene, hexa-boron nitride or the like.

The second object may comprise a portion, piece or chip of material. The material may be a crystalline material. The material may comprise, or be formed from, a thin film or a 2D material such as graphene, hexa-boron nitride or the like.

Such a method may enable the spatial registration of portions, pieces or chips of material relative to one another. The surface to which the second object is fixed or attached may be a surface of a motion control stage.

The first object may be detachably attached to the motion control stage.

The first object may be detachably attached to a first substrate or wafer, wherein the first substrate or wafer is fixed to the motion control stage.

The second object may comprise a feature, a structure, a target area, a target region or a second component defined on a second substrate or wafer, wherein the second substrate or wafer is fixed to the motion control stage.

The surface to which the second object is fixed or attached may be a surface of the second substrate or wafer.

Such a method may enable the alignment of a first component relative to a feature, a structure, a target area, a target region or a second component defined on a substrate or a wafer.

Using single-pixel detection to measure the optical power of at least a portion of the light that is reflected from the first and second objects and the one or more surface regions adjacent to the second object may comprise using a single-pixel detector to measure the optical power of at least a portion of the light that is reflected from the first and second objects and the one or more surface regions adjacent to the second object.

Using single-pixel detection to measure the optical power of at least a portion of the light that is reflected from the first and second objects and the one or more surface regions adjacent to the second object may comprise using a multi-pixel detector to measure the total integrated optical power of at least a portion of the light that is reflected from the first and second objects and the one or more surface regions adjacent to the second object and that is incident across a plurality of the pixels of the multi-pixel detector.

The light may comprise light of any kind. The light may comprise white light. The light may comprise coherent light. The light may comprise visible or infrared light.

The method may comprise detaching the first object from the motion control stage.

The method may comprise detaching the first object from the first substrate.

The method may comprise holding the first object and moving the first object and the motion control stage apart. The method may comprise holding the first object and moving the motion control stage away from the first object.

The method may comprise holding the first object spaced apart from the motion control stage and the second object to permit the motion control stage to move the second object relative to the first object.

The method may comprise aligning a tool, head, stamp, probe or holder with respect to the first object.

The method may comprise engaging the first object with the tool, head, stamp, probe or holder.

The method may comprise using the tool, head, stamp, probe or holder to hold the first object.

The method may comprise using the tool, head, stamp, probe or holder to detach the first object from the motion control stage.

The method may comprise using the tool, head, stamp, probe or holder to move the first object away from the motion control stage.

The method may comprise using the motion control stage to move the second object relative to the first object so as to align the first and second objects relative to one another until the measured optical power is maximised or minimised.

The method may comprise bringing the first and second objects together until the first and second objects are aligned and in engagement.

The method may comprise:

using a tool, head, stamp, probe or holder to hold the first object until the first and second objects are aligned and in engagement; and then

using the tool, head, stamp, probe or holder to release the first object to permit attachment of the first and second objects.

The method may comprise using the motion control stage to move the second object towards the first object until the first and second objects are aligned and in engagement.

The method may comprise using the tool, head, stamp, probe or holder to move the first object towards the second object until the first and second objects are aligned and in engagement.

The method may comprise attaching the first and second objects together while the first and second objects are aligned.

Such a method may be used in the micro-assembly of the first and second objects, for example for transfer printing the first object onto the second object.

Attaching the first and second objects together may comprise using a differential adhesion method and/or capillary bonding to attach the first and second objects.

Attaching the first and second objects together may comprise bonding the first and second objects together using an intermediate adhesive material or agent such as an intermediate adhesion layer.

Attaching the first and second objects together may comprise soldering the first and second objects.

The method may comprise flipping the first object over before attaching the first and second objects.

The first object may comprise a lithographic mask and the second object may comprise a work-piece e.g. a substrate or a wafer. The work-piece may comprise photoresist to be exposed to visible and/or UV light through the lithographic mask.

It should be understood that any one or more of the features of any one of the foregoing aspects of the present disclosure may be combined with any one or more of the features of any of the other foregoing aspects of the present disclosure.

### BRIEF DESCRIPTION OF THE DRAWINGS

Various apparatus and methods for use in spatially registering first and second objects will now be described by way of non-limiting example only with reference to the following drawings of which:

FIG. 1 is a schematic of a system for use in spatially registering first and second objects;

FIG. 2 is a plan view of a table of a motion control stage of the system of FIG. 1 with first and second substrates fixed to an upper surface of the table, the first substrate defining a component and a first marker and the second substrate defining a target area and a second marker;

FIG. 3A is a plan view of the first substrate of FIG. 2 illustrating a method of determining a position and orientation of the first marker in a frame of reference of the motion control stage according to a method for use in spatially registering first and second objects using the system of FIG. 1;

FIG. 3B is a plan view of the second substrate of FIG. 2 illustrating a method of determining a position and orientation of the second marker in the frame of reference of the motion control stage according to the method for use in spatially registering first and second objects using the system of FIG. 1;

FIG. 4 is a plan view of the table of the motion control stage of the system of FIG. 1 with first and second substrates fixed to the upper surface of the table, the first substrate defining a component and the second substrate defining a target area and a second marker;

FIG. 5A is a plan view of the first substrate of FIG. 4 illustrating a method of determining a position and orientation of the component in the frame of reference of the motion control stage according to a first alternative method for use in spatially registering first and second objects using the system of FIG. 1;

FIG. 5B is a plan view of the second substrate of FIG. 4 illustrating a method of determining a position and orientation of the second marker in the frame of reference of the motion control stage according to the first alternative method for use in spatially registering first and second objects using the system of FIG. 1;

FIG. 6 is a plan view of the table of the motion control stage of the system of FIG. 1 with first and second substrates fixed to the upper surface of the table, the first substrate defining a component and a first marker and the second substrate defining a target area;

FIG. 7A is a plan view of the first substrate of FIG. 6 illustrating a method of determining a position and orientation of the first marker in the frame of reference of the motion control stage according to a second alternative method for use in spatially registering first and second objects using the system of FIG. 1;

FIG. 7B is a plan view of the second substrate of FIG. 6 illustrating a method of determining a position and orientation of the target area in the frame of reference of the motion control stage according to the second alternative method for use in spatially registering first and second objects using the system of FIG. 1;

FIG. 8 is a plan view of the table of the motion control stage of the system of FIG. 1 with first and second substrates fixed to the upper surface of the table, the first substrate defining a component and the second substrate defining a target area;

FIG. 9A is a plan view of the first substrate of FIG. 8 illustrating a method of determining a position and orientation of the component in the frame of reference of the motion control stage according to a third alternative method for use in spatially registering first and second objects using the system of FIG. 1;

FIG. 9B is a plan view of the second substrate of FIG. 8 illustrating a method of determining a position and orientation of the target area in the frame of reference of the motion control stage according to the third alternative method for use in spatially registering first and second objects using the system of FIG. 1;

FIG. 10 is a plan view of the table of the motion control stage of the system of FIG. 1 with a component and a second substrate fixed to the upper surface of the table, the component defining a first marker and the second substrate defining a target area and a second marker;

FIG. 11A is a plan view of the component of FIG. 10 illustrating a method of determining a position and orientation of the first marker in the frame of reference of the motion control stage according to a fourth alternative method for use in spatially registering first and second objects using the system of FIG. 1;

FIG. 11B is a plan view of the second substrate of FIG. 10 illustrating a method of determining a position and orientation of the second marker in the frame of reference of the motion control stage according to the fourth alternative method for use in spatially registering first and second objects using the system of FIG. 1;

FIG. 12 is a plan view of the table of the motion control stage of the system of FIG. 1 with a component and a second substrate fixed to the upper surface of the table, the second substrate defining a target area and a second marker;

FIG. 13A is a plan view of the component of FIG. 12 illustrating a method of determining a position and orientation of the component in the frame of reference of the motion control stage according to a fifth alternative method for use in spatially registering first and second objects using the system of FIG. 1;

FIG. 13B is a plan view of the second substrate of FIG. 12 illustrating a method of determining a position and orientation of the second marker in the frame of reference of the motion control stage according to the fifth alternative method for use in spatially registering first and second objects using the system of FIG. 1;

FIG. 14 is a plan view of the table of the motion control stage of the system of FIG. 1 with a component and a second substrate fixed to the upper surface of the table, the second substrate defining a target area;

FIG. 15A is a plan view of the component of FIG. 14 illustrating a method of determining a position and orientation of the component in the frame of reference of the motion control stage according to a sixth alternative method for use in spatially registering first and second objects using the system of FIG. 1;

FIG. 15B is a plan view of the second substrate of FIG. 14 illustrating a method of 30 determining a position and orientation of the target area in the frame of reference of the motion control stage according to the sixth alternative method for use in spatially registering first and second objects using the system of FIG. 1;

FIG. 16 is a plan view of the table of the motion control stage of the system of FIG. 1 with 35 first and second substrates fixed to the upper surface of the table, the first substrate defining a component, a first marker and a further first marker, and the second substrate defining a target area, a second marker and a further second marker;

FIG. 17A is a plan view of the first substrate of FIG. 16 illustrating a method of determining a position and orientation of the first marker in the frame of reference of the motion control stage according to a further alternative method for use in spatially registering first and second objects using the system of FIG. 1;

FIG. 17B is a plan view of the second substrate of FIG. 16 illustrating a method of determining a position and orientation of the second marker in the frame of reference of the motion control stage according to the further alternative method for use in spatially registering first and second objects using the system of FIG. 1;

FIG. 18 is a schematic of an alternative system for use in spatially registering first and 15 second objects;

FIG. 19A is a side view of first and second objects at a first stage of a first method for use in spatial registering the first and second objects using the alternative system of FIG. 18 when the first and second objects are misaligned;

FIG. 19B is a side view of the first and second objects at a second stage of the first method for use in spatial registering the first and second objects using the alternative system of FIG. 18 when the first and second objects are partially overlapping;

FIG. 19C is a side view of the first and second objects at a third stage of the first method for use in spatial registering the first and second objects using the alternative system of FIG. 18 when the first and second objects are aligned;

FIG. 19D shows a plot of the measured optical power reflected from the first and second 30 objects using the alternative system of FIG. 18 during the first method for use in spatial registering the first and second objects illustrated with reference to FIGS. 19A-19C;

FIG. 20A is a side view of first and second objects at a first stage of a second method for use in spatial registering the first and second objects using the alternative system of 35 FIG. 18 when the first and second objects are misaligned;

FIG. 20B is a side view of the first and second objects at a second stage of the second method for use in spatial registering the first and second objects using the alternative system of FIG. 18 when the first and second objects are partially overlapping;

FIG. 20C is a side view of the first and second objects at a third stage of the second method for use in spatial registering the first and second objects using the alternative system of FIG. 18 when the first and second objects are aligned; and

FIG. 20D shows a plot of the measured optical power reflected from the first and second objects using the alternative system of FIG. 18 during the second method for use in spatial registering the first and second objects illustrated with reference to FIGS. 20A-20C.

### DETAILED DESCRIPTION OF THE DRAWINGS

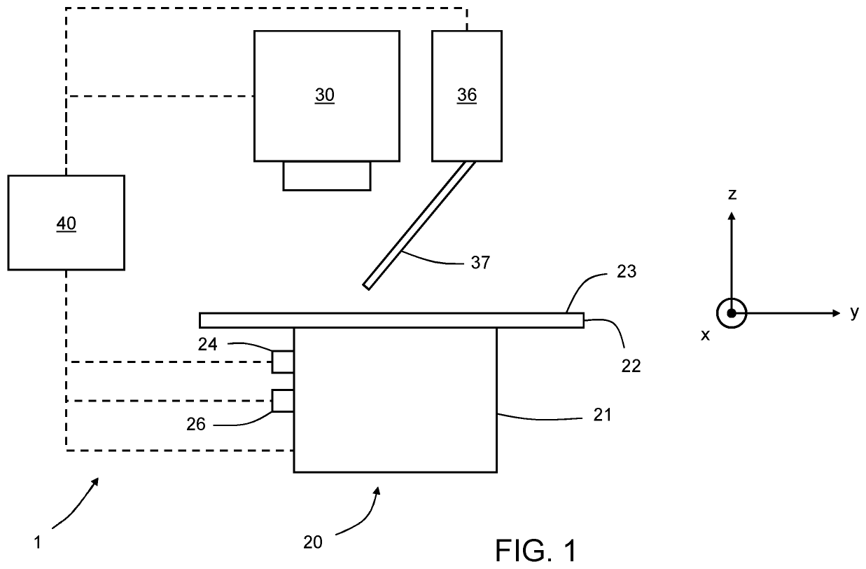

Referring initially to FIG. 1, there is shown a system generally designated 1 for use in spatially registering first and second objects (not shown in FIG. 1). The system 1 includes a motion control stage generally designated 20 having a base 21 and a table 22, wherein the table 22 is movable relative to the base 21. As will be described in more details below, in use, first and second objects (not shown in FIG. 1) are fixed to an upper surface 23 of the table 22 in an unknown spatial relationship.

Although not shown explicitly in FIG. 1, one of ordinary skill in the art will understand that the motion control stage 20 includes one or more actuators for controlling the position and orientation of the table 22 relative to the base 21 within a frame of reference of the motion control stage 20 as indicated by the x, y and z directions illustrated in FIG. 1. The motion control stage 20 includes one or more position sensors 24 for sensing relative x, y and z positions of the table 22 relative to the base 21 and one or more orientation sensors 26 for sensing a relative orientation or degree of rotation of the table 22 relative to the base 21 about the z-axis.

The system 1 further includes an imaging system 30 mounted above the upper surface 23 of the table 22 of the motion control stage 20 for acquiring images of one or more objects located on the upper surface 23. The imaging system 30 has a fixed spatial relationship relative to the base 21 of the motion control stage 20. The imaging system includes a microscope and a camera arranged so that the camera can acquire images of one or more objects located on the upper surface 23 of the table 22 of the motion control stage 20 through the microscope.

The system 1 further includes a “pick-and-place” tool 36 mounted above the upper surface 23 of the table 22 of the motion control stage 20. The pick-and-place tool 36 includes a head portion in the form of a polydimethylsiloxane (PDMS) stamp 37 for engaging and holding an object such as a component. As will be described in more detail below, the tool 36 is configured to pick a first object, to hold the first object, and to release the first object once the first object is in engagement with a second object. The system 1 further includes a controller in the form of a computing resource 40. As indicated by the dashed lines in FIG. 1, the computing resource 40 is configured for communication with the one or more actuators (not shown), the one or more position sensors 24, the one or more orientation sensors 26, the imaging system 30, and the tool 36.

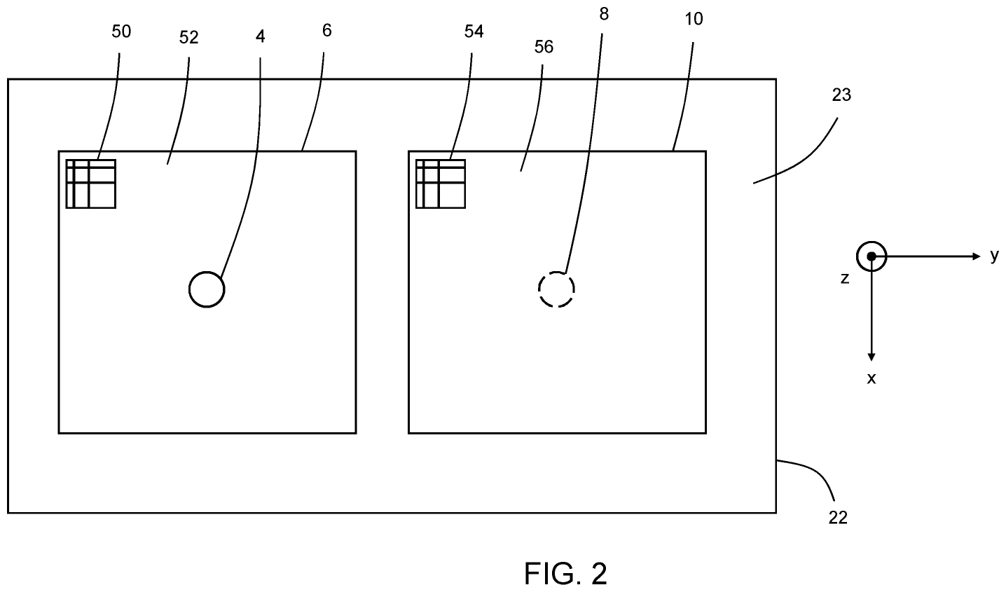

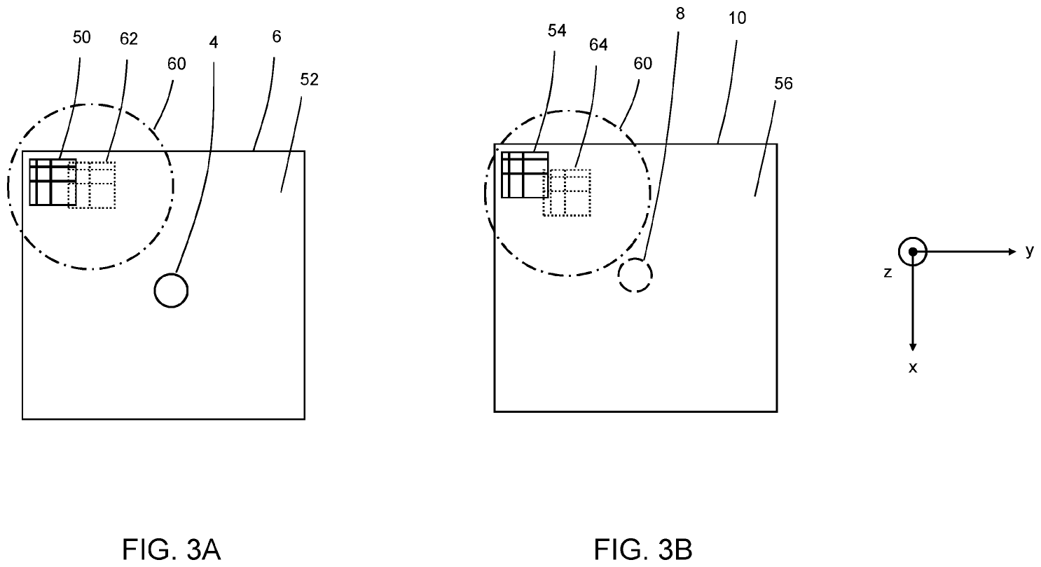

Referring to FIG. 2, there is shown an example of a first object in the form of a component 4 defined on a first substrate 6 and an example of a second object in the form of a target area 8 (shown in dashed lines) defined on a second substrate 10 on the surface 23 of the table 22 of the system 1. Although the first and second substrates 6, 10 are shown in FIGS. 2, 3A and 3B as being generally aligned along the x- and y-axes, it should be understood that, in general, the first and second substrates 6, 10 are misaligned with respect to the x- and y-axes.

As will be described in more detail below, the system 1 is capable of detaching the component 4 from the first substrate 6 and subsequently transferring the component 4 to the target area 8 on the second substrate 10.

The first substrate 6 has an upper surface 52 defining a first marker 50. The component 4 has a known position and orientation relative to the first marker 50. The second substrate 10 has an upper surface 56 defining a second marker 54. The target area 8 has a known position and orientation relative to the second marker 54. The target area 8 has the same size and shape as the component 4.

A method for use in spatially registering first and second objects will now be described with reference to FIGS. 3A and 3B. As indicated by the dotted-dashed lines in FIGS. 3A and 3B, the imaging system 30 defines a field-of-view (FOV) 60. In FIG. 3A, the table 22 of the motion control stage 20 is positioned relative to the imaging system 30 such that the first marker 50 is located within the FOV 60. In FIG. 3B, the table 22 of the motion control stage 20 is positioned relative to the imaging system 30 such that the second marker 54 is located within the FOV 60.

Referring now to FIG. 3A, the method for use in spatially registering for use in spatially registering first and second objects begins with the computing resource 40 determining the position and orientation of the component 4 in the frame of reference of the motion control stage 20. As will be described in more detail below, the computing resource 40 uses one or more acquired images of the first marker 50 to determine the position and orientation of the first marker 50 in the frame of reference of the motion control stage 20 and the computing resource 40 then uses the known position and orientation of the component 4 relative to the first marker 50 to determine the position and orientation of the component 4 in the frame of reference of the motion control stage 20.

The computing resource 40 determines the position and orientation of the first marker 50 in the frame of reference of the motion control stage 20 based at least in part on one or more acquired images of the first marker 50 with the aid of a fixed virtual image 62 of the first marker 50. The fixed virtual image 62 is stored in a memory of the computing resource 40 and has a fixed spatial relationship relative to the FOV 60 of the imaging system 30. In the example method illustrated in FIG. 3A, the fixed virtual image 62 of the first marker 50 is located in the centre of the FOV 60 of the imaging system 30 with a fixed orientation relative to the FOV 60 of the imaging system 30. Although the fixed virtual image 62 of the first marker 50 is shown in FIG. 3A, it should be understood that the fixed virtual image 62 of the first marker 50 is not necessarily displayed in the FOV 60 of the imaging system 30. The fixed virtual image 62 of the first marker 50 has the same size and shape as the first marker 50. The first marker 50 and the fixed virtual image 62 of the first marker 50 include features that are rotationally asymmetric and aperiodic in two dimensions such that there is a unique relative spatial alignment between the first marker 50 and the fixed virtual image 62 of the first marker 50 for which all of the features of the first marker 50 and all of the features of the fixed virtual image 62 of the first marker 50 are aligned. In FIG. 3A, the fixed virtual image 62 of the first marker 50 is shown with the same orientation as the first marker 50 but with the fixed virtual image 62 of the first marker 50 only partially overlapping the first marker 50 such that the first marker 50 and the fixed virtual image 62 of the first marker 50 are misaligned.

The computing resource 40 determines the position and orientation of the first marker 50 in the frame of reference of the motion control stage 20 by:

(i) causing the imaging system 30 to acquire an image of the first marker 50 when the first marker 50 is in the FOV 60 of the imaging system 30;

(ii) determining a degree of similarity between the acquired image of the first marker 50 and the fixed virtual image 62 of the first marker 50;

(iii) responsive to determining that the degree of similarity between the acquired image of the first marker 50 and the fixed virtual image 62 of the first marker 50 does not comply with a predetermined criterion, the computing resource 40 controls the actuators of the motion control stage 20 to translate and/or rotate the table 22 of the motion control stage 20 in the x-y plane with respect to the FOV 60 of the imaging system 30 while maintaining the first marker 50 in the FOV 60 of the imaging system 30 and repeats steps (i) and (ii) until the degree of similarity between the acquired image of the first marker 50 and the fixed virtual image 62 of the first marker 50 complies with the predetermined criterion;

(iv) using the position sensors 24 to measure a corresponding position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20 when the degree of similarity between the acquired image of the first marker 50 and the fixed virtual image 62 of the first marker 50 complies with the predetermined criterion; and

(v) determining the position and orientation of the first marker 50 in the frame of reference of the motion control stage 20 based on the measured position and orientation of the table 22 of the motion control stage 20 relative to the body 21 of the motion control stage 20 when the degree of similarity between the acquired image of the first marker 50 and the fixed virtual image 62 of the first marker 50 complies with the predetermined criterion.

The computing resource 40 determines the degree of similarity by evaluating a cross-correlation value between the acquired image of the first marker 50 and the fixed virtual image 62 of the first marker 50. The computing resource 40 determines that the degree of similarity complies with the predetermined criterion when the cross-correlation value has a maximum value.

The computing resource 40 then determines the position and orientation of the component 4 in the frame of reference of the motion control stage 20 from the determined position and orientation of the first marker 50 in the frame of reference of the motion control stage 20 and the known position and orientation of the component 4 relative to the first marker 50.

The accuracy with which the position of the component 4 is determined depends on factors including the size of the features, the pixel density of the imaging system, and the wavelength of light used, but may be in a range from 1 μm to 1 nm. The accuracy with which the orientation of the component 4 is determined depends on the same factors and may be in the range 0.001-1 mrad.

Referring now to FIG. 3B, the method for use in spatially registering first and second objects continues with the computing resource 40 determining the position and orientation of the target area 8 in the frame of reference of the motion control stage 20. As will be described in more detail below, the computing resource 40 uses one or more acquired images of the second marker 54 to determine the position and orientation of the second marker 54 in the frame of reference of the motion control stage 20 and the computing resource 40 then uses the known position and orientation of the target area 8 relative to the second marker 54 to determine the position and orientation of the target area 8 in the frame of reference of the motion control stage 20.

The computing resource 40 determines the position and orientation of the second marker 54 in the frame of reference of the motion control stage 20 based at least in part on one or more acquired images of the second marker 54 with the aid of a fixed virtual image 64 of the second marker 54. The fixed virtual image 64 is stored in a memory of the computing resource 40 and has a fixed spatial relationship relative to the FOV 60 of the imaging system 30. In the example method illustrated in FIG. 3B, the fixed virtual image 64 of the second marker 54 is located in the centre of the FOV 60 of the imaging system 30 with a fixed orientation relative to the FOV 60 of the imaging system 30. Although the fixed virtual image 64 of the second marker 54 is shown in FIG. 3B, it should be understood that the fixed virtual image 64 of the second marker 54 is not necessarily displayed in the FOV 60 of the imaging system 30. The fixed virtual image 64 of the second marker 54 has the same size and shape as the second marker 54. The second marker 54 and the fixed virtual image 64 of the second marker 54 include features that are rotationally asymmetric and aperiodic in two dimensions such that there is a unique relative spatial alignment between the second marker 54 and the fixed virtual image 64 of the second marker 54 for which all of the features of the second marker 54 and all of the features of the fixed virtual image 64 of the second marker 54 are aligned. In FIG. 3B, the fixed virtual image 64 of the second marker 54 is shown with the same orientation as the second marker 54 but with the fixed virtual image 64 of the second marker 54 only partially overlapping the second marker 54 such that the second marker 54 and the fixed virtual image 64 of the second marker 54 are misaligned.

The computing resource 40 determines the position and orientation of the second marker 54 in the frame of reference of the motion control stage 20 by:

(i) causing the imaging system 30 to acquire an image of the second marker 54 when the second marker 54 is in the FOV 60 of the imaging system 30;

(ii) determining a degree of similarity between the acquired image of the second marker 54 and the fixed virtual image 64 of the second marker 54;

(iii) responsive to determining that the degree of similarity between the acquired image of the second marker 54 and the fixed virtual image 64 of the second marker 54 does not comply with a predetermined criterion, the computing resource 40 controls the actuators of the motion control stage 20 to translate and/or rotate the table 22 of the motion control stage 20 in the x-y plane with respect to the FOV 60 of the imaging system 30 while maintaining the second marker 54 in the FOV 60 of the imaging system 30 and repeats steps (i) and (ii) until the degree of similarity between the acquired image of the second marker 54 and the fixed virtual image 64 of the second marker 54 complies with the predetermined criterion;

(iv) using the position sensors 24 to measure a corresponding position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20 when the degree of similarity between the acquired image of the second marker 54 and the fixed virtual image 64 of the second marker 54 complies with the predetermined criterion; and

(v) determining the position and orientation of the second marker 54 in the frame of reference of the motion control stage 20 based on the measured position and orientation of the table 22 of the motion control stage 20 relative to the body 21 of the motion control stage 20 when the degree of similarity between the acquired image of the second marker 54 and the fixed virtual image 64 of the second marker 54 complies with the predetermined criterion.

The computing resource 40 determines the degree of similarity by evaluating a cross-correlation value between the acquired image of the second marker 54 and the fixed virtual image 64 of the second marker 54. The computing resource 40 determines that the degree of similarity complies with the predetermined criterion when the cross-correlation value has a maximum value.

The computing resource 40 then determines the position and orientation of the target area 8 in the frame of reference of the motion control stage 20 from the determined position and orientation of the second marker 54 in the frame of reference of the motion control stage 20 and the known position and orientation of the target area 8 relative to the second marker 54.

The accuracy with which the position of the target area 8 is determined depends on factors including the size of the features, the pixel density of the imaging system, and the wavelength of light used but may be in a range from 1 μm to 1 nm. The accuracy with which the orientation of the target area 8 is determined depends on the same factors and may be in the range 0.001-1 mrad.

As will be described in more detail below, the method for use in spatially registering first and second objects continues with the computing resource 40 determining the spatial relationship between the component 4 and the target area 8 in the frame of reference of the motion control stage 20 based on the determined position and orientation of the component 4 in the frame of reference of the motion control stage 20 and the determined position and orientation of the target area 8 in the frame of reference of the motion control stage 20.

The pick and place tool 36 is locked in position relative to the base of 21 of the motion control stage 20 such that the PDMS stamp 37 of the pick and place tool 36 is positioned in the FOV 60 of the imaging system 30 at a position in z above a z-level of an upper surface of the component 4. If required, the motion control stage 20 is used to align the component 4 in x-y relative to the PDMS stamp 37 of the pick and place tool 36 in the FOV 60 of the imaging system 30. One of ordinary skill in the art will understand that the PDMS stamp 37 has reversible adhesion properties that may be used to pick up the component 4 and place the component 4 at the target area 8 of the second substrate 10 in a highly controllable manner. Specifically, once the component 4 is aligned in x-y relative to the PDMS stamp 37, the table 22 of the motion control stage 20 is moved along the z-axis towards the PDMS stamp 37 until the component 4 and the PDMS stamp 37 come into engagement. The table 22 of the motion control stage 20 is then moved along the z-axis away from the PDMS stamp 37. The adhesion properties of the PDMS stamp 37 cause the PDMS stamp 37 to hold the component 4 and to cause the component 4 to become detached from the first substrate 6 so that the PDMS stamp 37 holds the component 4 clear of the first and second substrates 6, 10. The computing resource 40 then controls the actuators of the motion control stage 20 so as to translate and/or rotate the table 22 of the motion control stage 20 in x-y relative to the component 4 (thereby also translating and/or rotating the first and second substrates 6, 10 in x-y relative to the component 4) based on the determined position and orientation of the target area 8 on the second substrate 10 in the frame of reference of the motion control stage 20 relative to the position and orientation of the component 4 when attached to the first substrate 6 in the frame of reference of the motion control stage 20 until the component 4 and the target area 8 on the second substrate 10 are aligned in translation and rotation in x-y, but spaced apart in z. The computing resource 40 then controls the actuators of the motion control stage 20 so as to move the table 22 (and therefore also the first and second substrates 6, 10) in z until the component 4 and the target area 8 on the second substrate 10 are in engagement. Engagement of the component 4 and the target area 8 on the second substrate 10 results in the PDMS stamp 37 releasing the component 4 and attachment of the component 4 to the second substrate 10 at the target area 8 as a consequence of differential adhesion or capillary bonding between the component 4 and the second substrate 10.

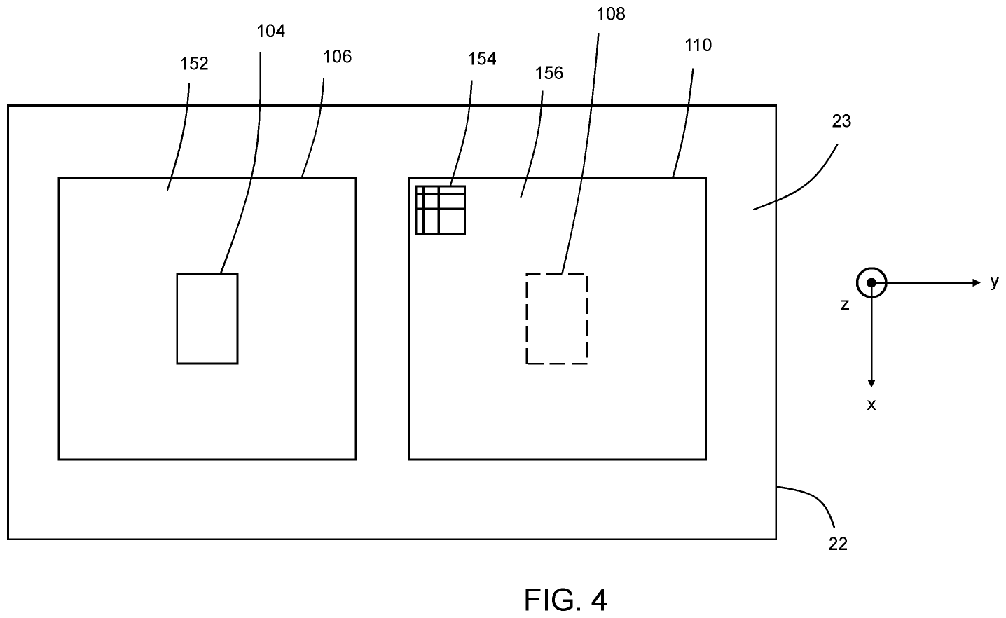

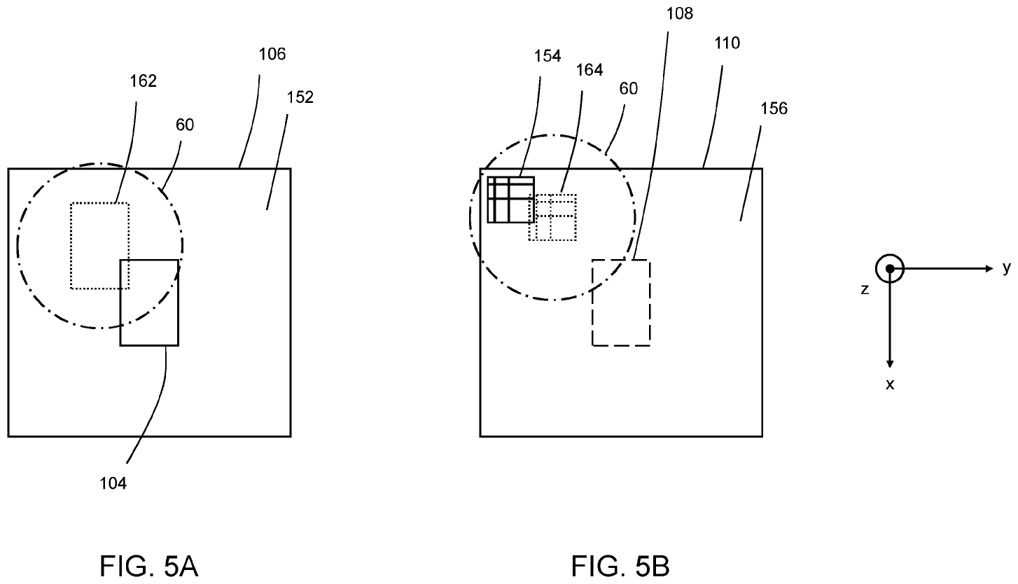

A first alternative method for use in spatially registering first and second objects will now be described with reference to FIGS. 4, 5A and 5B. Features of the first alternative spatial registration method described with reference to FIGS. 4, 5A and 5B are identified with reference numerals that are incremented by “100” relative to the reference numerals used to identify like features of the spatial registration method described with reference to FIGS. 2, 3A and 3B. Referring to FIG. 4, there is shown a first substrate 106 and a second substrate 110 located on the upper surface 23 of the table 22 of the motion control stage 20. A first object in the form of a component 104 is defined on the first substrate 106. A second object in the form of a target area 108 is defined on the second substrate 110. The second substrate 10 has an upper surface 156 defining a second marker 154. The target area 108 has a known position and orientation relative to the second marker 154. The target area 108 has the same size and shape as the component 104. In contrast to the first substrate 6 described with reference to FIGS. 2, 3A and 3B, the first substrate 106 does not include a first marker corresponding to the first marker 50. The first and second substrates 106, 110, and therefore also the component 104 and the target area 108, are fixed to the upper surface 23 of the table 22 in an unknown spatial relationship. Although the first and second substrates 106, 110 are shown in FIGS. 4, 5A and 5B as being generally aligned along the x- and y-axes, it should be understood that, in general, the first and second substrates 106, 110 are misaligned with respect to the x- and y-axes.

Referring now to FIG. 5A, the first alternative spatial registration method differs from the first method in that the position and orientation of the component 104 in the frame of reference of the motion control stage 20 is determined based at least in part on one or more acquired images of the component 104 instead of one or more acquired images of a first marker like the first marker 50 described with reference to FIGS. 2, 3A and 3B.

The computing resource 40 determines the position and orientation of the component 104 in the frame of reference of the motion control stage 20 based at least in part on one or more acquired images of the component 104 with the aid of a fixed virtual image 162 of the component 104. The fixed virtual image 162 of the component 104 is stored in a memory of the computing resource 40 and has a fixed spatial relationship with respect to the FOV 60 of the imaging system 30. In the example method illustrated in FIG. 5A, the fixed virtual image 162 of the component 104 is located in the centre of the FOV 60 of the imaging system 30 with a fixed orientation relative to the FOV 60 of the imaging system 30. Although the fixed virtual image 162 of the component 104 is shown in FIG. 5A, it should be understood that the fixed virtual image 162 of the component 104 is not necessarily displayed in the FOV 60 of the imaging system 30. The fixed virtual image 162 of the component 104 has the same size and shape as the component 104. In FIG. 5A, the fixed virtual image 162 of the component 104 is shown with the same orientation as the component 104 but only partially overlapping the component 104, and is therefore misaligned relative to the component 104.

The first alternative spatial registration method begins with the computing resource 40 determining the position and orientation of the component 104 in the frame of reference of the motion control stage 20 based at least in part on the one or more acquired images of the component 104. Specifically, the computing resource 40:

(i) causes the imaging system 30 to acquire an image of the component 104 when the component 104 is in the FOV 60 of the imaging system 30;

(ii) determines a degree of similarity between the acquired image of the component 104 and the fixed virtual image 162 of the component 104;

(iii) responsive to determining that the degree of similarity between the acquired image of the component 104 and the fixed virtual image 162 of the component 104 does not comply with a predetermined criterion, the computing resource 40 controls the actuators of the motion control stage 20 so as to translate and/or rotate the table 22 of the motion control stage 20 in the x-y plane with respect to the FOV 60 of the imaging system 30 while maintaining the component 104 in the FOV 60 of the imaging system 30 and repeats steps (i) and (ii) until the degree of similarity between the acquired image of the component 104 and the fixed virtual image 162 of the component 104 complies with a predetermined criterion;

(iv) uses the position sensors 24 to measure a corresponding relative position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20 when the degree of similarity between the acquired image of the component 104 and the fixed virtual image 162 of the component 104 complies with the predetermined criterion; and

(v) determines the position and orientation of the component 104 in the frame of reference of the motion control stage 20 based on the measured position and orientation of the table 22 of the motion control stage 20 relative to the body 21 of the motion control stage 20 when the degree of similarity between the acquired image of the component 104 and the fixed virtual image 162 of the component 104 complies with the predetermined criterion.

The computing resource 40 determines the degree of similarity by evaluating a cross-correlation value between the acquired image of the component 104 and the fixed virtual image 162 of the component 104. The computing resource 40 determines that the degree of similarity complies with the predetermined criterion when the cross-correlation value has a maximum value.

Referring now to FIG. 5B, the computing resource 40 determines the position and orientation of the second marker 150 in the frame of reference of the motion control stage 20 based at least in part on one or more acquired images of the second marker 150 with the aid of a fixed virtual image 164 of the second marker 150 and uses the position and orientation of the second marker 150 in the frame of reference of the motion control stage 20 and the known position and orientation of the target area 108 relative to the second marker 150 to determine the position and orientation of the target area 108 in the frame of reference of the motion control stage 20 in a way that is identical to the way in which the computing resource 40 determines the position and orientation of the target area 8 in the frame of reference of the motion control stage 20 according to the spatial registration method described with reference to FIGS. 2, 3A and 3B.

One of ordinary skill in the art will understand that the first alternative spatial registration method further includes steps of detaching the component 104 from the first substrate 106, moving the table 22 (and therefore also the first and second substrates 106, 110) relative to the component 104, and attaching the component 104 to the target area 108 on the second substrate 110, which steps are identical to the corresponding steps of the spatial registration method described with reference to FIGS. 2, 3A and 3B.

Imaging the component 104 according to the first alternative spatial registration method instead of imaging a first marker like the first marker 50 according to the spatial registration method described with reference to FIGS. 2, 3A and 3B, enables the position and orientation of the component 104 to be found directly without there being a need to create, use, or know the position of the component 104 relative to a first marker on the first substrate 106 like the first marker 50 on the first substrate 6 described with reference to FIGS. 2, 3A and 3B. As such, the first alternative spatial registration method may be used when the component 4 has a random or unknown position and/or a random or unknown orientation on the first substrate 106. The disadvantage of the first alternative spatial registration method is that the position and orientation information that is obtained for the component 104 may be less reliable, precise, or accurate than the position and orientation information that is obtained for the component 4 using the spatial registration method described with reference to FIGS. 2, 3A and 3B. For example, if the component 104 were round, the first alternative spatial registration method would not provide any orientation information for the component 104.

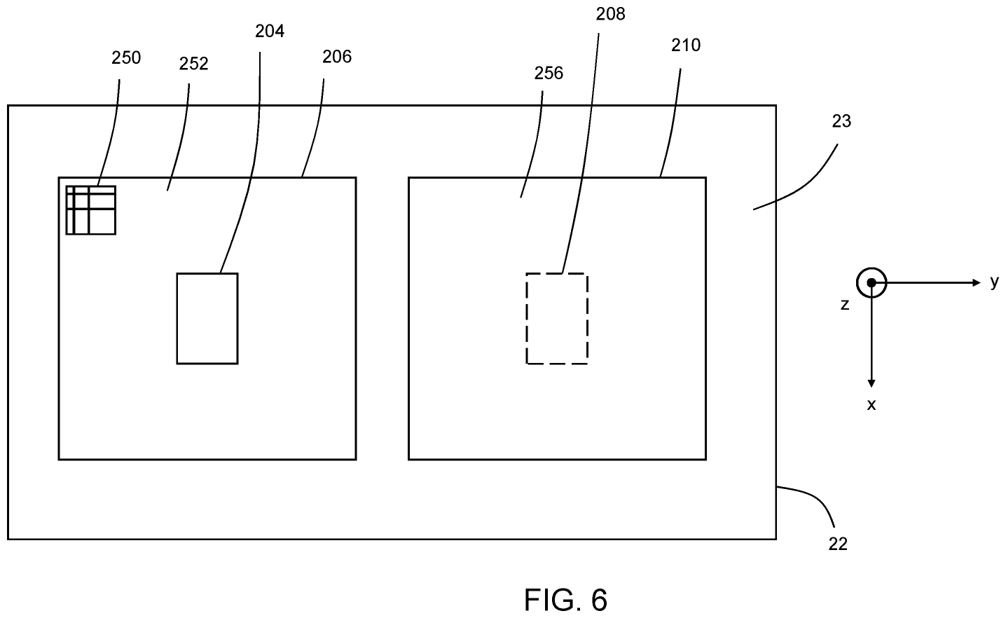

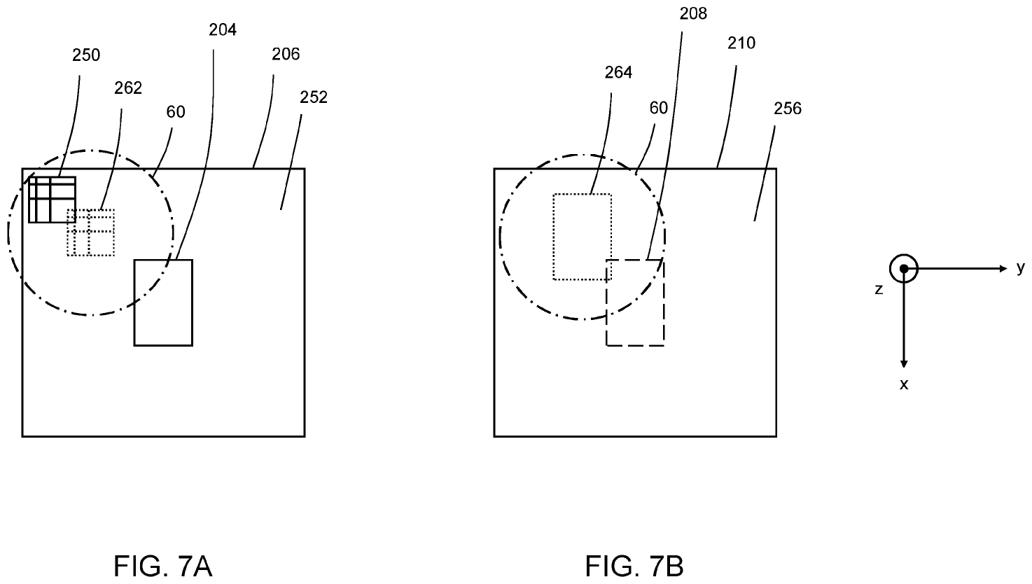

A second alternative method for use in spatially registering first and second objects will now be described with reference to FIGS. 6, 7A and 7B. Features of the second alternative spatial registration method described with reference to FIGS. 6, 7A and 7B are identified with reference numerals that are incremented by “200” relative to the reference numerals used to identify like features of the spatial registration method described with reference to FIGS. 2, 3A and 3B. Referring to FIG. 6, there is shown a first substrate 206 and a second substrate 210 located on the upper surface 23 of the table 22 of the motion control stage 20. A first object in the form of a component 204 is defined on the first substrate 206. The first substrate 206 has an upper surface 252 defining a first marker 250. The component 204 has a known position and orientation relative to the first marker 250. A second object in the form of a target area 208 is defined on the second substrate 210. The target area 208 has the same size and shape as the component 204. In contrast to the second substrate 10 described with reference to FIGS. 2, 3A and 3B, the second substrate 210 does not include a second marker corresponding to the second marker 54. The first and second substrates 206, 210, and therefore also the component 204 and the target area 208, are fixed to the upper surface 23 of the table 22 in an unknown spatial relationship. Although the first and second substrates 206, 210 are shown in FIGS. 6, 7A and 7B as being generally aligned along the x- and y-axes, it should be understood that, in general, the first and second substrates 206, 210 are misaligned with respect to the x- and y-axes.

Referring now to FIG. 7A, the second alternative spatial registration method begins with the computing resource 40 determining the position and orientation of the first marker 250 in the frame of reference of the motion control stage 20 based at least in part on one or more acquired images of the first marker 250 with the aid of a fixed virtual image 262 of the first marker 250 and the computing resource 40 using the position and orientation of the first marker 250 in the frame of reference of the motion control stage 20 and the known position and orientation of the component 204 relative to the first marker 250 to determine the position and orientation of the component 204 in the frame of reference of the motion control stage 20 in a way that is identical to the way in which the computing resource 40 determines the position and orientation of the component 4 in the frame of reference of the motion control stage 20 according to the spatial registration method described with reference to FIGS. 2, 3A and 3B.

Referring now to FIG. 7B, the second alternative spatial registration method differs from the first spatial registration method in that the computing resource 40 determines the position and orientation of the target area 208 in the frame of reference of the motion control stage 20 based at least in part on one or more acquired images of the target area 208 instead of one or more acquired images of a second marker like the second marker 54 described with reference to FIGS. 2, 3A and 3B.

As will be described in more detail below, the computing resource 40 determines the position and orientation of the target area 208 in the frame of reference of the motion control stage 20 based at least in part on one or more acquired images of the target area 208 with the aid of a fixed virtual image 264 of the target area 208.

The fixed virtual image 264 of the target area 208 is stored in a memory of the computing resource 40 and has a fixed spatial relationship with respect to the FOV 60 of the imaging system 30. In the example method illustrated in FIG. 7B, the fixed virtual image 264 of the target area 208 is located in the centre of the FOV 60 of the imaging system 30 with a fixed orientation relative to the FOV 60 of the imaging system 30. Although the fixed virtual image 264 of the target area 208 is shown in FIG. 7B, it should be understood that the fixed virtual image 264 of the target area 208 is not necessarily displayed in the FOV 60 of the imaging system 30. The fixed virtual image 264 of the target area 208 has the same size and shape as the target area 208. In FIG. 7B, the fixed virtual image 264 of the target area 208 is shown with the same orientation as the target area 208 but only partially overlapping the target area 208, and is therefore misaligned relative to the target area 208.

The second alternative spatial registration method continues with the computing resource 40 determining the position and orientation of the target area 208 in the frame of reference of the motion control stage 20 based at least in part on the one or more acquired images of the target area 208. Specifically, the computing resource 40:

(i) causes the imaging system 30 to acquire an image of the target area 208 when the target area 208 is in the FOV 60 of the imaging system 30;

(ii) determines a degree of similarity between the acquired image of the target area 208 and the fixed virtual image 264 of the target area 208;

(iii) responsive to determining that the degree of similarity between the acquired image of the target area 208 and the fixed virtual image 264 of the target area 208 does not comply with a predetermined criterion, the computing resource 40 controls the actuators of the motion control stage 20 to translate and/or rotate the table 22 of the motion control stage 20 in the x-y plane with respect to the FOV 60 of the imaging system 30 while maintaining the target area 208 in the FOV 60 of the imaging system 30 and repeats steps (i) and (ii) until the degree of similarity between the acquired image of the target area 208 and the fixed virtual image 264 of the target area 208 complies with the predetermined criterion;

(iv) uses the position sensors 24 to measure a corresponding relative position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20 when the degree of similarity between the acquired image of the target area 208 and the fixed virtual image 264 of the target area 208 complies with the predetermined criterion; and

(v) determines the position and orientation of the target area 208 in the frame of reference of the motion control stage 20 based on the measured position and orientation of the table 22 of the motion control stage 20 relative to the body 21 of the motion control stage 20 when the degree of similarity between the acquired image of the target area 208 and the fixed virtual image of the target area 208 complies with the predetermined criterion.

The computing resource 40 determines the degree of similarity by evaluating a cross-correlation value between the acquired image of the target area 208 and the fixed virtual image 264 of the target area 208. The computing resource 40 determines that the degree of similarity complies with the predetermined criterion when the cross-correlation value has a maximum value.

One of ordinary skill in the art will understand that the second alternative spatial registration method further includes steps of detaching the component 204 from the first substrate 206, moving the table 22 (and therefore also the first and second substrates 206, 210) relative to the component 204, and attaching the component 204 to the target area 208 on the second substrate 110, which steps are identical to the corresponding steps of the spatial registration method described with reference to FIGS. 2, 3A and 3B.

Imaging the target area 208 according to the second alternative spatial registration method instead of imaging a second marker like the second marker 54 according to the spatial registration method described with reference to FIGS. 2, 3A and 3B, enables the position and orientation of the target area 208 to be found directly without there being a need to create, use, or know the position of the target area 208 relative to a second marker on the second substrate 210 like the second marker 54 on the second substrate 210 described with reference to FIGS. 2, 3A and 3B. As such, the second alternative spatial registration method may be used when the target area 208 has a random or unknown position and/or a random or unknown orientation on the second substrate 210. The disadvantage of the second alternative spatial registration method is that the position and orientation information that is obtained for the target area 208 may be less reliable, precise, or accurate than the position and orientation information that is obtained for the target area 8 using the spatial registration method described with reference to FIGS. 2, 3A and 3B. For example, if the target area 208 were round, the second alternative spatial registration method would not provide any orientation information for the target area 208.

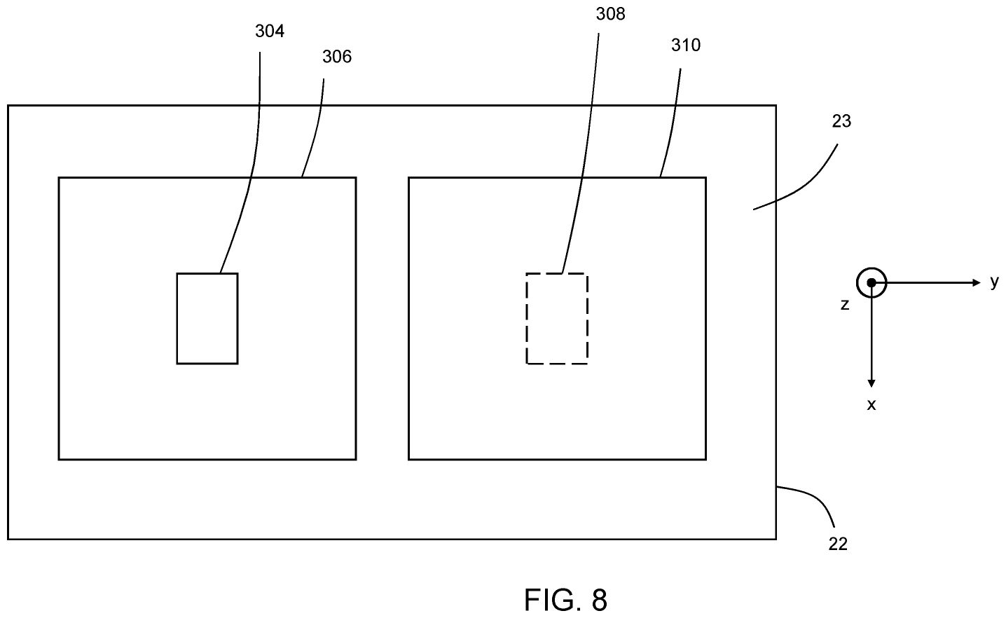

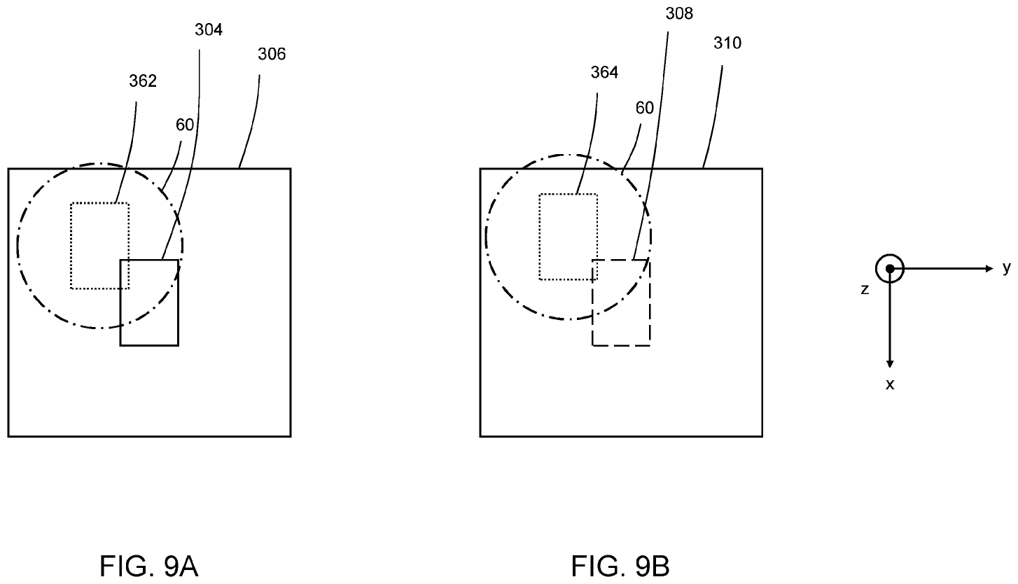

A third alternative method for use in spatially registering first and second objects will now be described with reference to FIGS. 8, 9A and 9B. Features of the third alternative spatial registration method described with reference to FIGS. 8, 9A and 9B are identified with reference numerals that are incremented by “300” relative to the reference numerals used to identify like features of the spatial registration method described with reference to FIGS. 2, 3A and 3B. Although the first and second substrates 306, 310 are shown in FIGS. 8, 9A and 9B as being generally aligned along the x- and y-axes, it should be understood that, in general, the first and second substrates 306, 310 are misaligned with respect to the x- and y-axes.

Referring to FIG. 8, there is shown a first substrate 306 and a second substrate 310 located on the upper surface 23 of the table 22 of the motion control stage 20. A first object in the form of a component 304 is defined on the first substrate 306. A second object in the form of a target area 308 is defined on the second substrate 310. The first and second substrates 306, 310, and therefore also the component 304 and the target area 308, are fixed to the upper surface 23 of the table 22 in an unknown spatial relationship. In contrast to the first substrate 6 described with reference to FIGS. 2, 3A and 3B, the first substrate 306 does not include a first marker corresponding to the first marker 50. Furthermore, in contrast to the second substrate 10 described with reference to FIGS. 2, 3A and 3B, the second substrate 310 does not include a second marker corresponding to the second marker 54.

As illustrated in FIG. 9A, the third alternative spatial registration method begins with the computing resource 40 determining the position and orientation of the component 304 in the frame of reference of the motion control stage 20 based at least in part on one or more acquired images of the component 304 with the aid of a fixed virtual image 362 of the component 304 in a way which is identical to the way in which the computing resource 40 determines the position and orientation of the component 104 in the frame of reference of the motion control stage 20 based at least in part on one or more acquired images of the component 104 with the aid of the fixed virtual image 162 of the component 104 as described above in relation to the first alternative spatial registration method with reference to FIGS. 4, 5A and 5B.

As illustrated in FIG. 9B, the third alternative spatial registration method continues with the computing resource 40 determining the position and orientation of the target area 308 in the frame of reference of the motion control stage 20 based at least in part on one or more acquired images of the target area 308 with the aid of a fixed virtual image 364 of the target area 308 in a way which is identical to the way in which the computing resource 40 determines the position and orientation of the target area 208 in the frame of reference of the motion control stage 20 based at least in part on one or more acquired images of the target area 208 with the aid of the fixed virtual image 264 of the target area 208 in relation to second alternative spatial registration method described above with reference to FIGS. 6, 7A and 7B.

One of ordinary skill in the art will understand that the third alternative spatial registration method further includes steps of detaching the component 304 from the first substrate 306, moving the table 22 (and therefore also the first and second substrates 306, 310) relative to the component 304, and attaching the component 304 to the target area 308 on the second substrate 310, which steps are identical to the corresponding steps of the spatial registration method described with reference to FIGS. 2, 3A and 3B.

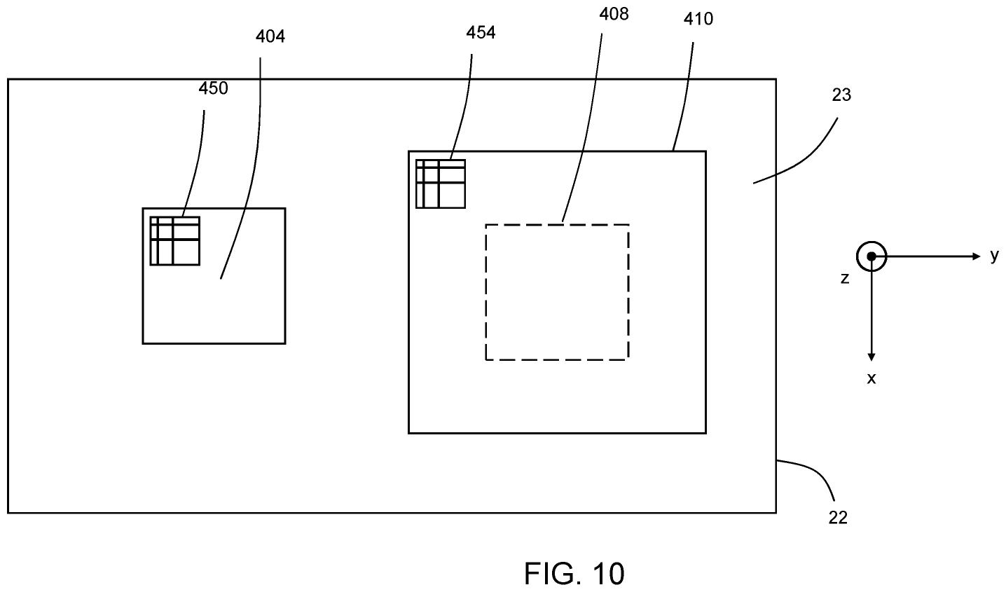

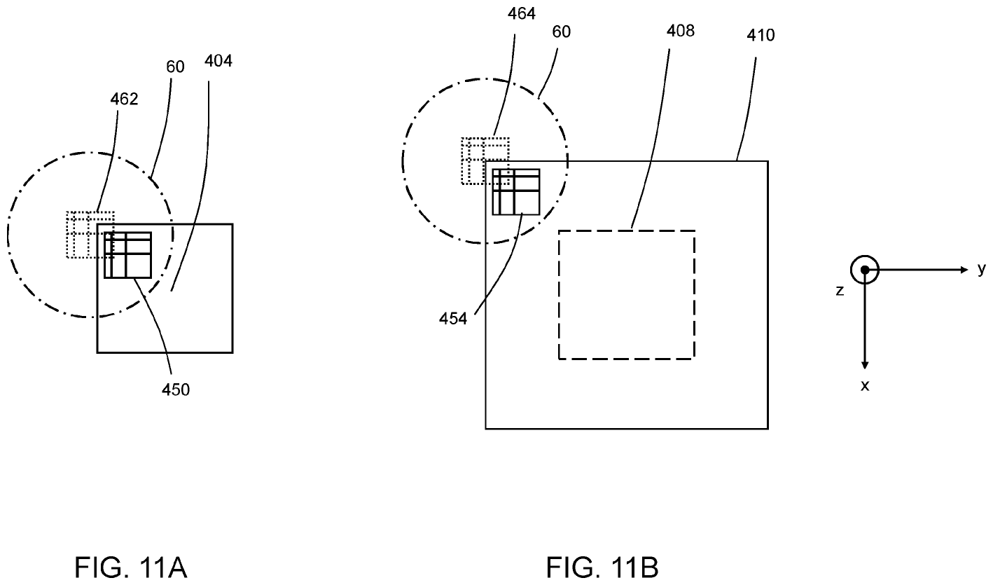

A fourth alternative method for use in spatially registering first and second objects will now be described with reference to FIGS. 10, 11A and 11B. Features of the fourth alternative spatial registration method described with reference to FIGS. 10, 11A and 11B are identified with reference numerals that are incremented by “400” relative to the reference numerals used to identify like features of the spatial registration method described with reference to FIGS. 2, 3A and 3B. Referring to FIG. 10, there is shown a first object in the form of a component 404 and a second object in the form of a target area 408 of a second substrate 410 located on the upper surface 23 of the table 22 of the motion control stage 20. The component 404 defines a first marker 450. The second substrate 410 defines a second marker 454. The target area 408 has a known position and orientation relative to the second marker 454. The target area 408 has the same size and shape as the component 404. The component 404, the second substrate 410 and therefore also the target area 408, are fixed to the upper surface 23 of the table 22 in an unknown spatial relationship. In contrast to the first substrate 6 that includes a first marker 50 described with reference to FIGS. 2, 3A and 3B, the first marker 450 is defined on the component 404. Also, the component 404 is not defined on a first substrate like the first substrate 6. It should be understood that although the component 404 and the second substrate 410 are shown in FIGS. 10, 11A and 11B as being generally aligned along the x- and y-axes, it should be understood that, in general, the component 404 and the second substrate 410 are misaligned with respect to the x- and y-axes.

As illustrated in FIG. 11A, the fourth alternative spatial registration method begins with the computing resource 40 determining the position and orientation of the first marker 450 in the frame of reference of the motion control stage 20 based at least in part on one or more acquired images of the first marker 450 with the aid of a fixed virtual image 462 of the first marker 450 in a way that is identical to the way in which the computing resource 40 determines the position and orientation of the first marker 50 in the frame of reference of the motion control stage 20 according to the spatial registration method described with reference to FIGS. 2, 3A and 3B.

As illustrated in FIG. 11B, the fourth alternative spatial registration method continues with the computing resource 40 determining the position and orientation of the second marker 454 in the frame of reference of the motion control stage 20 based at least in part on one or more acquired images of the second marker 454 with the aid of a fixed virtual image 464 of the second marker 454 in a way that is identical to the way in which the computing resource 40 determines the position and orientation of the second marker 54 in the frame of reference of the motion control stage 20 according to the spatial registration method described with reference to FIGS. 2, 3A and 3B.

One of ordinary skill in the art will understand that the fourth alternative spatial registration method further includes steps of detaching the component 404 from the surface 23 of the table 22 of the motion control stage 20, moving the table 22 (and therefore also the second substrate 310) relative to the component 404, and attaching the component 404 to the target area 408 on the second substrate 410, which steps are essentially identical to the corresponding steps of the spatial registration method described with reference to FIGS. 2, 3A and 3B.

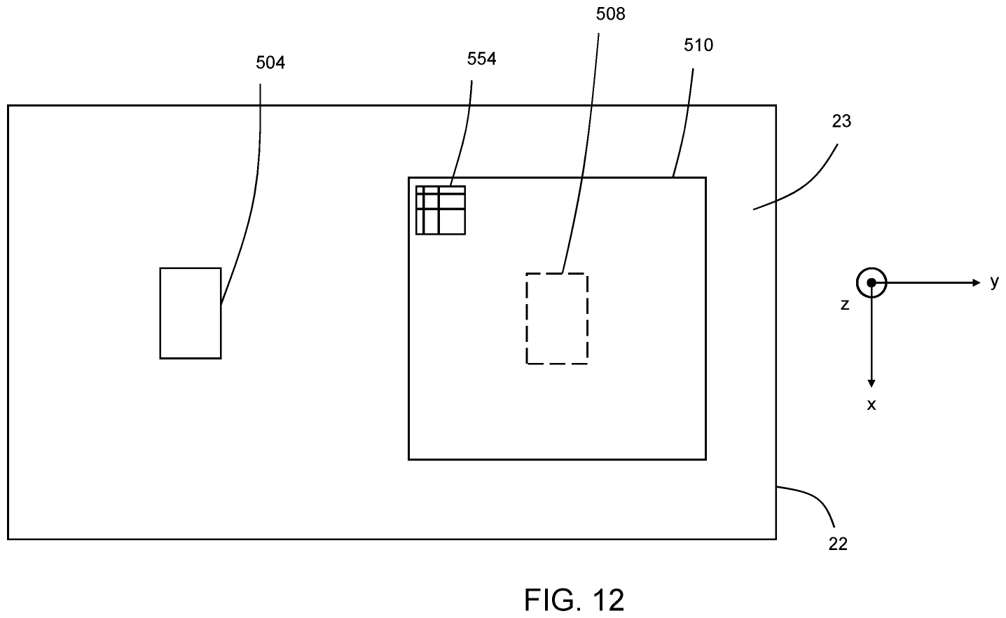

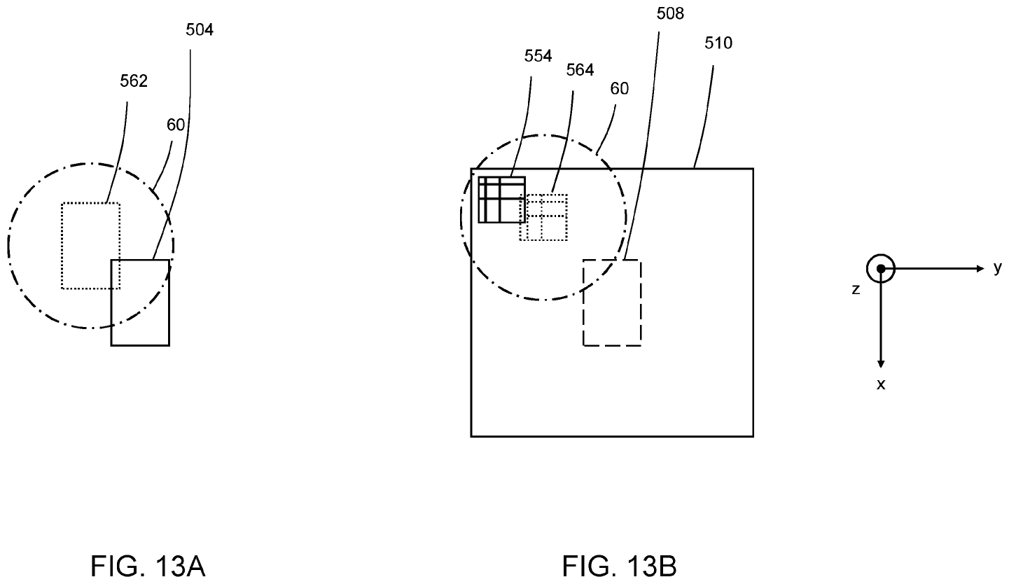

A fifth alternative method for use in spatially registering first and second objects will now be described with reference to FIGS. 12, 13A and 13B. Features of the fifth alternative spatial registration method described with reference to FIGS. 12, 13A and 13B are identified with reference numerals that are incremented by “500” relative to the reference numerals used to identify like features of the spatial registration method described with reference to FIGS. 2, 3A and 3B. Referring to FIG. 12, there is shown a first object in the form of a component 504 and a second object in the form of a target area 508 of a second substrate 510 located on the upper surface 23 of the table 22 of the motion control stage 20. The second substrate 510 defines a second marker 554. The target area 508 has a known position and orientation relative to the second marker 554. The target area 508 has the same size and shape as the component 504. The component 504, the second substrate 510 and therefore also the target area 508, are fixed to the upper surface 23 of the table 22 in an unknown spatial relationship. In contrast to the first substrate 6 that includes a first marker 50 described with reference to FIGS. 2, 3A and 3B, the component 504 does not define a first marker like the first marker 50, nor is the component 504 defined on a first substrate like the first substrate 6. It should be understood that although the component 504 and the second substrate 510 are shown in FIGS. 12, 13A and 13B as being generally aligned along the x- and y-axes, it should be understood that, in general, the component 504 and the second substrate 510 are misaligned with respect to the x- and y-axes.

As illustrated in FIG. 13A, the fifth alternative spatial registration method begins with the computing resource 40 determining the position and orientation of the component 504 in the frame of reference of the motion control stage 20 based at least in part on one or more acquired images of the component 504 with the aid of a fixed virtual image 562 of the first marker 450 in a way that is identical to the way in which the computing resource 40 determines the position and orientation of the component 104 in the frame of reference of the motion control stage 20 according to the spatial registration method described with reference to FIGS. 4, 5A and 5B.

As illustrated in FIG. 13B, the fifth alternative spatial registration method continues with the computing resource 40 determining the position and orientation of the second marker 554 in the frame of reference of the motion control stage 20 based at least in part on one or more acquired images of the second marker 554 with the aid of a fixed virtual image 564 of the second marker 554 in a way that is identical to the way in which the computing resource 40 determines the position and orientation of the second marker 54 in the frame of reference of the motion control stage 20 according to the spatial registration method described with reference to FIGS. 2, 3A and 3B.

One of ordinary skill in the art will understand that the fifth alternative spatial registration method further includes steps of detaching the component 504 from the surface 23 of the table 22 of the motion control stage 20, moving the table 22 (and therefore also the second substrate 510) relative to the component 504, and attaching the component 504 to the target area 508 on the second substrate 510, which steps are essentially identical to the corresponding steps of the spatial registration method described with reference to FIGS. 2, 3A and 3B.

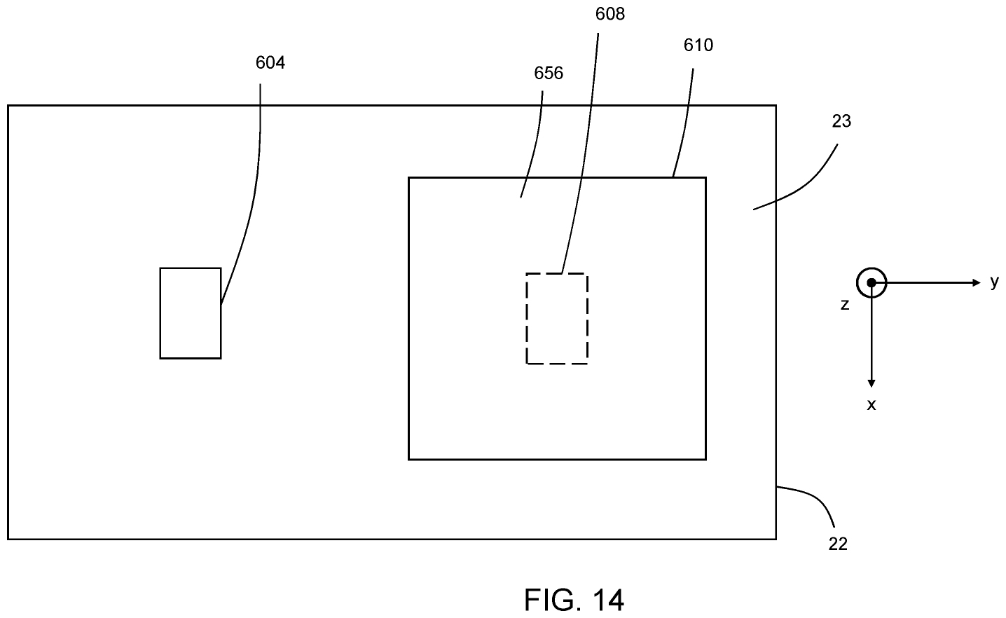

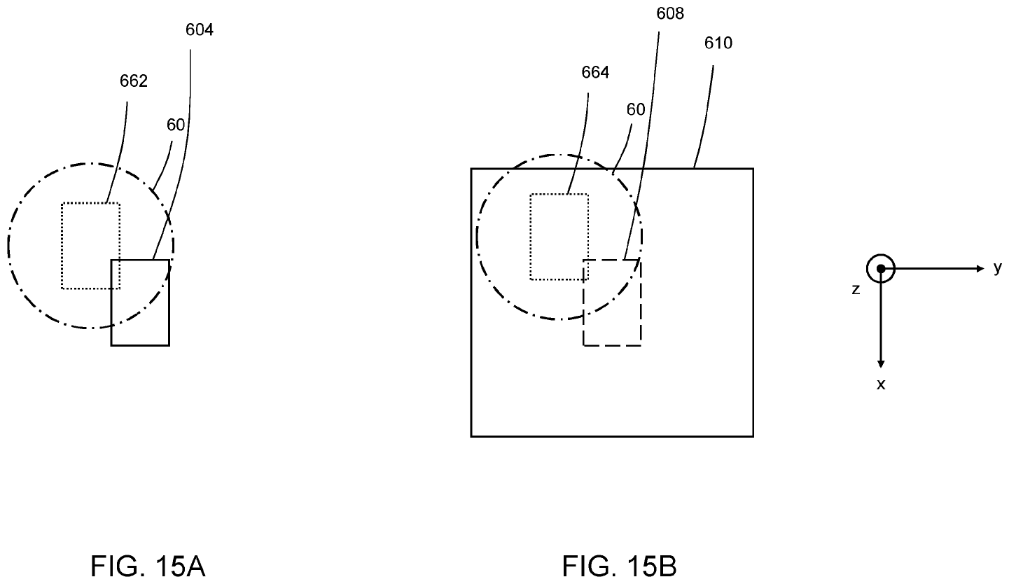

A sixth alternative method for use in spatially registering first and second objects will now be described with reference to FIGS. 14, 15A and 15B. Features of the fifth alternative spatial registration method described with reference to FIGS. 14, 15A and 15B are identified with reference numerals that are incremented by “600” relative to the reference numerals used to identify like features of the spatial registration method described with reference to FIGS. 2, 3A and 3B. Referring to FIG. 14, there is shown a first object in the form of a component 604 and a second object in the form of a target area 608 of a second substrate 610 located on the upper surface 23 of the table 22 of the motion control stage 20. The target area 608 has the same size and shape as the component 504. The component 604, the second substrate 610 and therefore also the target area 608, are fixed to the upper surface 23 of the table 22 in an unknown spatial relationship. In contrast to the first substrate 6 that includes a first marker 50 described with reference to FIGS. 2, 3A and 3B, the component 604 does not define a first marker like the first marker 50, nor is the component 604 defined on a first substrate like the first substrate 6. It should be understood that although the component 604 and the second substrate 610 are shown in FIGS. 14, 15A and 15B as being generally aligned along the x- and y-axes, it should be understood that, in general, the component 604 and the second substrate 610 are misaligned with respect to the x- and y-axes.

As illustrated in FIG. 15A, the sixth alternative spatial registration method begins with the computing resource 40 determining the position and orientation of the component 604 in the frame of reference of the motion control stage 20 based at least in part on one or more acquired images of the component 604 with the aid of a fixed virtual image 662 of the component 604 in a way that is identical to the way in which the computing resource 40 determines the position and orientation of the component 104 in the frame of reference of the motion control stage 20 according to the spatial registration method described with reference to FIGS. 4, 5A and 5B.

As illustrated in FIG. 15B, the sixth alternative spatial registration method continues with the computing resource 40 determining the position and orientation of the target area 608 in the frame of reference of the motion control stage 20 based at least in part on one or more acquired images of the target area 608 with the aid of a fixed virtual image 664 of the target area 608 in a way that is identical to the way in which the computing resource 40 determines the position and orientation of the target area 208 in the frame of reference of the motion control stage 20 according to the spatial registration method described with reference to FIGS. 6, 7A and 7B.

One of ordinary skill in the art will understand that the sixth alternative spatial registration method further includes steps of detaching the component 604 from the surface 23 of the table 22 of the motion control stage 20, moving the table 22 (and therefore also the second substrate 610) relative to the component 604, and attaching the component 604 to the target area 608 on the second substrate 610, which steps are essentially identical to the corresponding steps of the spatial registration method described with reference to FIGS. 2, 3A and 3B.

One of ordinary skill in the art will understand that various modifications are possible to the apparatus and methods described above. For example, each of the spatial registration methods described above with reference to FIGS. 1-15B typically includes sequentially determining a position and orientation of an object such as a component in a frame of reference of the motion control stage 20 by acquiring an image of the object or of a marker for each position and/or orientation of a plurality of different positions and/or orientations of the object in the FOV 60 of the imaging system 30, determining a degree of similarity between each acquired image of the object or of the marker and a fixed virtual image of the object or the marker having a fixed spatial relationship relative to the FOV 60 of the imaging system 30, and determining the position and orientation of the object or of the marker when the degree of similarity is a maximum. As such, each of the spatial registration methods described above with reference to FIGS. 1-15B typically requires multiple movements of the table 22 of the motion control stage 20 relative to the base 21 of the motion control stage 20.

A variant of each of the spatial registration methods described above with reference to FIGS. 1-15B comprises acquiring a single image of an object such as a component or of a marker, sequentially determining a degree of similarity between the single acquired image of the object or of the marker and each virtual image of a plurality of virtual images of the object or of the marker, each virtual image of the object or of the marker corresponding to a different position and/or orientation of the virtual image of the object or of the marker in the FOV 60 of the imaging system 30, and determining the position and orientation of the virtual image of the object or of the marker which maximises the degree of similarity. For example, with reference to FIGS. 2, 3A and 3B, the computing resource 40 may determine the position and orientation of the first marker 50 in the frame of reference of the motion control stage 20 by:

(i) causing the imaging system 30 to acquire an image of the first marker 50;

(ii) using the position sensors 24 to measure a position of the table 22 of the motion control stage 20 relative to the body 21 of the motion control stage 20 corresponding to the acquired image of the first marker 50 and using the orientation sensors 26 to measure an orientation of the table 22 of the motion control stage 20 relative to the body 21 of the motion control stage 20 corresponding to the acquired image of the first marker 50;

(iii) determining a degree of similarity between the acquired image of the first marker 50 and the virtual image 62 of the first marker 50;

(iv) responsive to determining that the degree of similarity between the acquired image of the first marker 50 and the virtual image 62 of the first marker 50 does not comply with a predetermined criterion, translating and/or rotating the virtual image 62 of the first marker 50 with respect to the FOV 60 of the imaging system 30 and repeating step (iii) until the degree of similarity between the acquired image of the first marker 50 and the virtual image 62 of the first marker 50 complies with the predetermined criterion;

(v) determining a corresponding relative position and orientation of the virtual image 62 of the first marker 50 with respect to the FOV 60 of the imaging system 30 when the degree of similarity between the virtual image 62 of the first marker 50 and the acquired image of the first marker 50 complies with the predetermined criterion; and

(vi) determining the position and orientation of the first marker 50 in the frame of reference of the motion control stage 20 based on the measured relative position and orientation of the table 22 of the motion control stage 20 relative to the body 21 of the motion control stage 20 corresponding to the acquired image of the first marker 50 and the determined relative position and orientation of the virtual image 62 of the first marker 50 with respect to the FOV 60 of the imaging system 30 when the degree of similarity between the virtual image 62 of the first marker 50 and the acquired image of the first marker 50 complies with the predetermined criterion.

The computing resource 40 determines the degree of similarity by evaluating a cross-correlation value between the acquired image of the first marker 50 and the virtual image 62 of the first marker 50. The computing resource 40 determines that the degree of similarity complies with the predetermined criterion when the cross-correlation value has a maximum value.

Similarly, with reference to FIGS. 2, 3A and 3B, the computing resource 40 may determine the position and orientation of the second marker 54 in the frame of reference of the motion control stage 20 by:

(i) causing the imaging system 30 to acquire an image of the second marker 54;

(ii) using the position sensors 24 to measure a position of the table 22 of the motion control stage 20 relative to the body 21 of the motion control stage 20 corresponding to the acquired image of the second marker 54 and using the orientation sensors 26 to measure an orientation of the table 22 of the motion control stage 20 relative to the body 21 of the motion control stage 20 corresponding to the acquired image of the second marker 54;

(iii) determining a degree of similarity between the acquired image of the second marker 54 and the virtual image 64 of the second marker 54;

(iv) responsive to determining that the degree of similarity between the acquired image of the second marker 54 and the virtual image 64 of the second marker 54 does not comply with a predetermined criterion, translating and/or rotating the virtual image 64 of the second marker 54 with respect to the FOV 60 of the imaging system 30 and repeating step (iii) until the degree of similarity between the acquired image of the second marker 54 and the virtual image 64 of the second marker 54 complies with the predetermined criterion;

(v) determining a corresponding relative position and orientation of the virtual image 64 of the second marker 54 with respect to the FOV 60 of the imaging system 30 when the degree of similarity between the virtual image 64 of the second marker 54 and the acquired image of the second marker 54 complies with the predetermined criterion; and

(vi) determining the position and orientation of the second marker 54 in the frame of reference of the motion control stage 20 based on the measured relative position and orientation of the table 22 of the motion control stage 20 relative to the body 21 of the motion control stage 20 corresponding to the acquired image of the second marker 54 and the determined relative position and orientation of the virtual image 64 of the second marker 54 with respect to the FOV 60 of the imaging system 30 when the degree of similarity between the virtual image 64 of the second marker 54 and the acquired image of the second marker 54 complies with the predetermined criterion.

The computing resource 40 determines the degree of similarity by evaluating a cross-correlation value between the acquired image of the second marker 54 and the virtual image 64 of the second marker 54. The computing resource 40 determines that the degree of similarity complies with the predetermined criterion when the cross-correlation value has a maximum value.

As another example, with reference to FIGS. 8, 9A and 9B, the computing resource 40 may determine the position and orientation of the component 304 in the frame of reference of the motion control stage 20 based at least in part on the one or more acquired images of the component 304 by:

(i) causing the imaging system 30 to acquire an image of the component 304;

(ii) using the position sensors 24 to measure a position of the table 22 of the motion control stage 20 relative to the body 21 of the motion control stage 20 corresponding to the acquired image of the component 304 and using the orientation sensors 26 to measure an orientation of the table 22 of the motion control stage 20 relative to the body 21 of the motion control stage 20 corresponding to the acquired image of the component 304;

(iii) determining a degree of similarity between the acquired image of the component 304 and the virtual image 362 of the component 304;

(iv) responsive to determining that the degree of similarity between the acquired image of the component 304 and the virtual image 362 of the component 304 does not comply with a predetermined criterion, translating and/or rotating the virtual image 362 of the component 304 with respect to the FOV 60 of the imaging system 30 and repeating step (iii) until the degree of similarity between the acquired image of the component 304 and the virtual image 362 of the component 304 complies with the predetermined criterion;

(v) determining a corresponding relative position and orientation of the virtual image 362 of the component 304 with respect to the FOV 60 of the imaging system 30 when the degree of similarity between the virtual image 362 of the component 304 and the acquired image of the component 304 complies with the predetermined criterion; and

(vi) determining the position and orientation of the component 304 in the frame of reference of the motion control stage 20 based on the measured relative position and orientation of the motion control stage 20 corresponding to the acquired image of the component 304 and the determined relative position and orientation of the virtual image 362 of the component 304 with respect to the FOV 60 of the imaging system 30 when the degree of similarity between the virtual image 362 of the component 304 and the acquired image of the component 304 complies with the predetermined criterion.

The computing resource 40 determines the degree of similarity by evaluating a cross-correlation value between the acquired image of the component 304 and the virtual image 362 of the component 304. The computing resource 40 determines that the degree of similarity complies with the predetermined criterion when the cross-correlation value has a maximum value.

Similarly, with reference to FIGS. 8, 9A and 9B, the computing resource 40 may determine the position and orientation of the target area 308 in the frame of reference of the motion control stage 20 based at least in part on the one or more acquired images of the target area 308 by:

(i) causing the imaging system 30 to acquire an image of the target area 308;

(ii) using the position sensors 24 to measure a position of the table 22 of the motion control stage 20 relative to the body 21 of the motion control stage 20 corresponding to the acquired image of the target area 308 and using the orientation sensors 26 to measure an orientation of the table 22 of the motion control stage 20 relative to the body 21 of the motion control stage 20 corresponding to the acquired image of the target area 308;

(iii) determining a degree of similarity between the acquired image of the target area 308 and the virtual image 364 of the target area 308;

(iv) responsive to determining that the degree of similarity between the acquired image of the target area 308 and the virtual image 364 of the target area 308 does not comply with a predetermined criterion, translating and/or rotating the virtual image 364 of the target area 308 with respect to the FOV 60 of the imaging system 30 and repeating step (iii) until the degree of similarity between the acquired image of the target area 308 and the virtual image 364 of the target area 308 complies with the predetermined criterion;

(v) determining a corresponding relative position and orientation of the virtual image 364 of the target area 308 with respect to the FOV 60 of the imaging system 30 when the degree of similarity between the virtual image 364 of the target area 308 and the acquired image of the target area 308 complies with the predetermined criterion; and

(vi) determining the position and orientation of the target area 308 in the frame of reference of the motion control stage 20 based on the measured relative position and orientation of the motion control stage 20 corresponding to the acquired image of the target area 308 and the determined relative position and orientation of the virtual image 364 of the target area 308 with respect to the FOV 60 of the imaging system 30 when the degree of similarity between the virtual image 364 of the target area 308 and the acquired image of the target area 308 complies with the predetermined criterion.

The computing resource 40 determines the degree of similarity by evaluating a cross-correlation value between the acquired image of the target area 308 and the virtual image 364 of the target area 308. The computing resource 40 determines that the degree of similarity complies with the predetermined criterion when the cross-correlation value has a maximum value.

One of ordinary skill in the art will understand that such variant methods for determining a position and orientation of an object such as a component in a frame of reference of the motion control stage 20 wherein the degree of similarity is determined sequentially between a single acquired image of the object or of a marker and each virtual image of a plurality of virtual images of the object or of the marker, wherein each virtual image of the object or of the marker corresponds to a different position and/or orientation of the virtual image of the object or of the marker in the FOV 60 of the imaging system 30, do not require any movement of the table 22 of the motion control stage 20 relative to the base 21 of the motion control stage 20 once the single image of the object or of the marker is acquired. Consequently, not only are such variant methods for determining a position and orientation of an object in a frame of reference of the motion control stage 20 faster than the spatial registration methods described above with reference to FIGS. 1-15B (which typically require multiple movements of the table 22 of the motion control stage 20 relative to the base 21 of the motion control stage 20), but such variant methods may also be more accurate than the spatial registration methods described above with reference to FIGS. 1-15B. For example, one of ordinary skill in the art will understand that the positional and rotational accuracy of such variant methods for determining a position and orientation of an object in a frame of reference of the motion control stage 20 are essentially limited only by the pixel size of the acquired image of the object or of the marker.

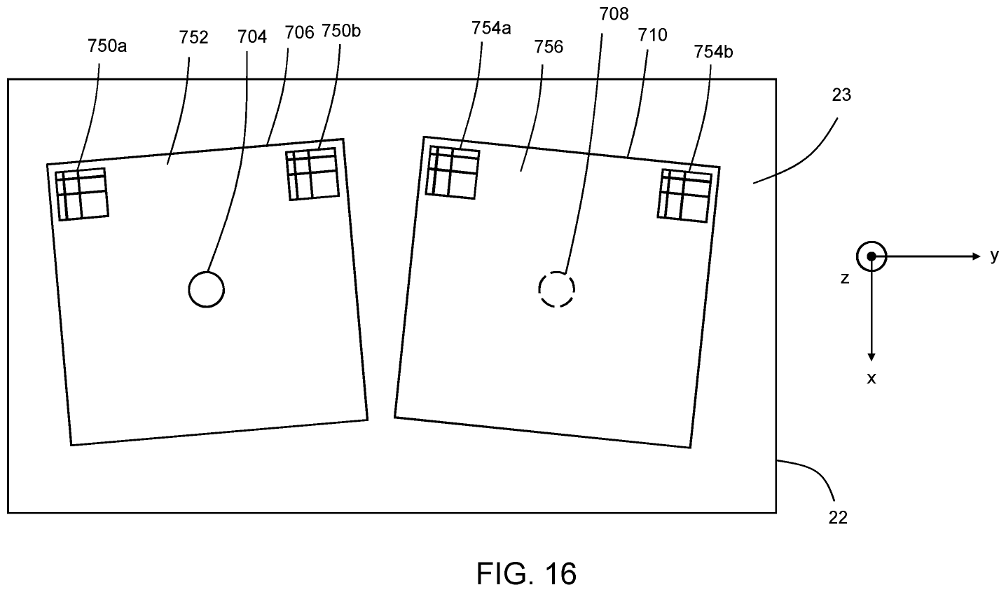

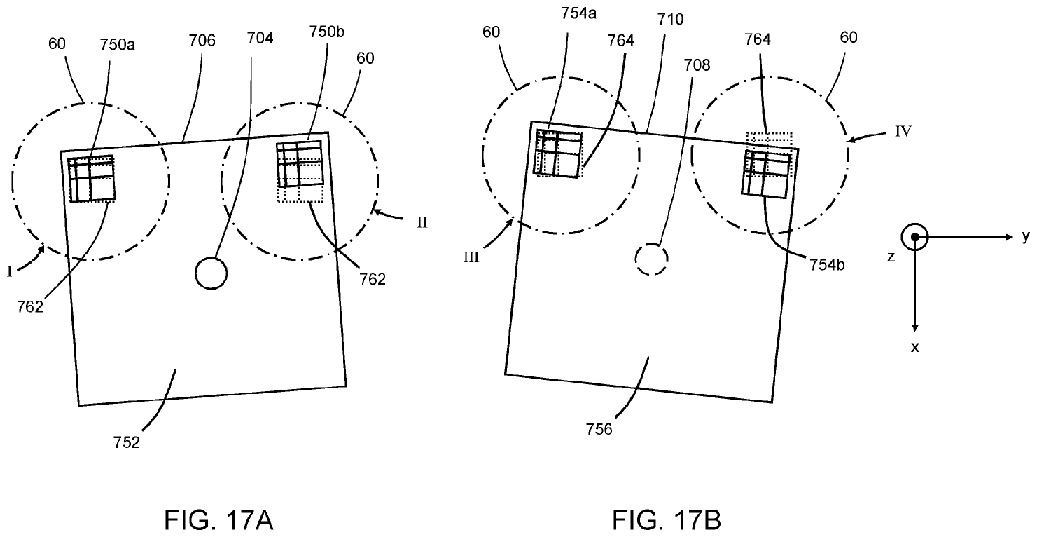

A further alternative method for use in spatially registering first and second objects will now be described with reference to FIGS. 16, 17A and 17B. Features of the further alternative spatial registration method described with reference to FIGS. 16, 17A and 17B are identified with reference numerals that are incremented by “700” relative to the reference numerals used to identify like features of the spatial registration method described with reference to FIGS. 2, 3A and 3B.

Referring to FIG. 16, there is shown an example of a first object in the form of a component 704 defined on a first substrate 706 and an example of a second object in the form of a target area 708 (shown in dashed lines) defined on a second substrate 710 on the surface 23 of the table 22 of the system 1.

The first substrate 706 has an upper surface 752 defining a first marker 750a and an identical further first marker 750b. The first marker 750a and the further first marker 750b have a known separation, for example because the first marker 750a and the further first marker 750 are defined simultaneously on the first substrate 706 using the same lithographic process. The component 704 has a known position and orientation relative to the first marker 750a and the further first marker 750b.

The second substrate 710 has an upper surface 756 defining a second marker 754a and a further second marker 754b. The second marker 754a and the further second marker 754b have a known separation, for example because the second marker 754a and the further second marker 754b are defined simultaneously on the second substrate 710 using the same lithographic process. The target area 708 has a known position and orientation relative to the second marker 754a and the further second marker 754b. The target area 708 has the same size and shape as the component 704.

It should be understood that the first and second substrates 706 and 710 are generally misaligned with the x- and y-axes and that the misalignment of the first and second substrates 706 and 710 with respect to the x- and y-axes has been exaggerated in FIGS. 16, 17A and 17B for the purposes of the following description.

The further alternative method for use in spatially registering first and second objects will now be described with reference to FIGS. 17A and 17B. As indicated by the dotted-dashed lines in FIGS. 17A and 17B, the imaging system 30 defines a field-of-view (FOV) 60.

Referring to FIG. 17A, the further alternative method for use in spatially registering for use in spatially registering first and second objects begins with the computing resource 40 determining the position and orientation of the first marker 750a in the frame of reference of the motion control stage 20. Specifically, the computing resource 40:

(i) causes the imaging system 30 to acquire an image of the first marker 750a when the first marker 750a is in the FOV 60 of the imaging system 30 as shown at inset I in FIG. 17A;

(ii) uses the position sensors 24 to measure a corresponding position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20; and

(iii) determines a degree of similarity between the acquired image of the first marker 750a and a virtual image 762 of the first marker 750a, which virtual image 762 of the first marker 750a has the same size and shape as the first marker 750a, and responsive to determining that the degree of similarity between the acquired image of the first marker 750a and the virtual image 762 of the first marker 750a does not comply with a predetermined criterion, translates the virtual image 762 of the first marker 750a in x and y with respect to the FOV 60 of the imaging system 30 until the degree of similarity between the acquired image of the first marker 750a and the virtual image 762 of the first marker 750a complies with the predetermined criterion.

The computing resource 40 determines the degree of similarity by evaluating a cross-correlation value between the acquired image of the first marker 750a and the virtual image 762 of the first marker 750a. The computing resource 40 determines that the degree of similarity complies with the predetermined criterion when the cross-correlation value has a maximum value.

The computing resource 40 then:

(iv) controls the actuators of the motion control stage 20 so as to translate the table 22 of the motion control stage 20 relative to the body 21 of the motion control stage 20 along a linear translation axis of the motion control stage 20 by a distance equal to the known separation between the first marker 750a and the further first marker 750b so that the further first marker 750b is in the FOV 60 of the imaging system 30 as shown at inset II in FIG. 17A.

Specifically, the computing resource 40 controls the actuators of the motion control stage 20 so as to translate the table 22 of the motion control stage 20 relative to the body 21 of the motion control stage 20 along the y-axis of the motion control stage 20 by a distance equal to the known separation between the first marker 750a and the further first marker 750b so that the further first marker 750b is in the FOV 60 of the imaging system 30 as shown at inset II in FIG. 17A. As a consequence of the misalignment of the first substrate 706 relative to the x- and y-axes, translating the table 22 of the motion control stage 20 relative to the body 21 of the motion control stage 20 along the y-axis of the motion control stage 20 by the distance equal to the known separation between the first marker 750a and the further first marker 750b, results in an offset between the further first marker 750b and the virtual image 762 of the further first marker 750b along the x-axis relative to the FOV 60 of the imaging system 30 as shown at inset II in FIG. 17A.

The computing resource 40 then:

(v) causes the imaging system 30 to acquire an image of the further first marker 750b when the further first marker 750b is in the FOV 60 of the imaging system 30 as shown at inset II in FIG. 17A;

(vi) uses the position sensors 24 to measure a corresponding position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20 when the further first marker 750b is in the FOV 60 of the imaging system 30 as shown at inset II in FIG. 17A; and

(vii) determines a degree of similarity between the acquired image of the further first marker 750b and the virtual image 762 of the further first marker 750b, and responsive to determining that the degree of similarity between the acquired image of the further first marker 750b and the virtual image 762 of the further first marker 750b does not comply with a predetermined criterion, translates the virtual image 762 of the further first marker 750b in x and y with respect to the FOV 60 of the imaging system 30 until the degree of similarity between the acquired image of the further first marker 750b and the virtual image 762 of the further first marker 750b complies with the predetermined criterion.

The computing resource 40 determines the degree of similarity by evaluating a cross-correlation value between the acquired image of the further first marker 750b and the virtual image 762 of the further first marker 750b. The computing resource 40 determines that the degree of similarity complies with the predetermined criterion when the cross-correlation value has a maximum value.

The computing resource 40 then:

(vii) determines the position and orientation of the first marker 750a in the frame of reference of the motion control stage 20 based on:
(a) the measured relative position of the table 22 of the motion control stage 20 relative to the body 21 of the motion control stage 20 corresponding to the acquired image of the first marker 750a;
(b) the relative position of the virtual image 762 of the first marker 750a with respect to the FOV 60 of the imaging system 30 when the degree of similarity between the virtual image 762 of the first marker 750a and the acquired image of the first marker 750a complies with the predetermined criterion;
(c) the measured relative position of the table 22 of the motion control stage 20 relative to the body 21 of the motion control stage 20 corresponding to the acquired image of the further first marker 750b; and
(d) the relative position of the virtual image 762 of the further first marker 750b with respect to the FOV 60 of the imaging system 30 when the degree of similarity between the virtual image 762 of the further first marker 750b and the acquired image of the further first marker 750b complies with the predetermined criterion.

One of skill in the art will understand that the method of determining the position and orientation of the first marker 750a in the frame of reference of the motion control stage 20 described above with reference to FIG. 17A enables the orientation of the first marker 750a to be determined in the frame of reference of the motion control stage 20 with greater accuracy than the methods described with reference to FIGS. 3A, 7A, and 11A.

The computing resource 40 then determines the position and orientation of the component 704 in the frame of reference of the motion control stage 20 from the determined position and orientation of the first marker 750a in the frame of reference of the motion control stage 20 and the known position and orientation of the component 704 relative to the first marker 750a.

The accuracy with which the position of the component 704 is determined in the frame of reference of the motion control stage 20 depends on factors including the size of the features, the pixel density of the imaging system, and the wavelength of light used, but may be in a range from 1 μm to 1 nm. The accuracy with which the orientation of the component 704 is determined in the frame of reference of the motion control stage 20 depends on the same factors and may be in the range 0.001-1 mrad.

Referring to FIG. 17B, the further alternative method for use in spatially registering for use in spatially registering first and second objects continues with the computing resource 40 determining the position and orientation of the second marker 754a in the frame of reference of the motion control stage 20. Specifically, the computing resource 40:

(i) causes the imaging system 30 to acquire an image of the second marker 754a when the second marker 754a is in the FOV 60 of the imaging system 30 as shown at inset III in FIG. 17B;

(ii) uses the position sensors 24 to measure a corresponding position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20; and

(iii) determines a degree of similarity between the acquired image of the second marker 754a and a virtual image 764 of the second marker 754a, which virtual image 764 of the second marker 754a has the same size and shape as the second marker 754a, and responsive to determining that the degree of similarity between the acquired image of the second marker 754a and the virtual image 764 of the second marker 754a does not comply with a predetermined criterion, translates the virtual image 764 of the second marker 754a in x and y with respect to the FOV 60 of the imaging system 30 until the degree of similarity between the acquired image of the second marker 754a and the virtual image 764 of the second marker 754a complies with the predetermined criterion.

The computing resource 40 determines the degree of similarity by evaluating a cross-correlation value between the acquired image of the second marker 754a and the virtual image 764 of the second marker 754a. The computing resource 40 determines that the degree of similarity complies with the predetermined criterion when the cross-correlation value has a maximum value.

The computing resource 40 then:

(iv) controls the actuators of the motion control stage 20 so as to translate the table 22 of the motion control stage 20 relative to the body 21 of the motion control stage 20 along a linear translation axis of the motion control stage 20 by a distance equal to the known separation between the second marker 754a and the further second marker 754b so that the further second marker 754b is in the FOV 60 of the imaging system 30 as shown at inset IV in FIG. 17B.

Specifically, the computing resource 40 controls the actuators of the motion control stage 20 so as to translate the table 22 of the motion control stage 20 relative to the body 21 of the motion control stage 20 along the y-axis of the motion control stage 20 by a distance equal to the known separation between the second marker 754a and the further second marker 754b so that the further second marker 754b is in the FOV 60 of the imaging system 30 as shown at inset IV in FIG. 17B. As a consequence of the misalignment of the second substrate 710 relative to the x- and y-axes, translating the table 22 of the motion control stage 20 relative to the body 21 of the motion control stage 20 along the y-axis of the motion control stage 20 by the distance equal to the known separation between the second marker 754a and the further second marker 754b, results in an offset between the further second marker 754b and the virtual image 764 of the further second marker 754b along the x-axis relative to the FOV 60 of the imaging system 30 as shown at inset IV in FIG. 17B.

The computing resource 40 then:

(v) causes the imaging system 30 to acquire an image of the further second marker 754b when the further second marker 754b is in the FOV 60 of the imaging system 30 as shown at inset IV in FIG. 17B;

(vi) uses the position sensors 24 to measure a corresponding position of the table 22 of the motion control stage 20 relative to the body 21 of the motion control stage 20 and the orientation sensors 26 to measure a corresponding relative orientation of the table 22 of the motion control stage 20 relative to the body 21 of the motion control stage 20 when the further second marker 750b is in the FOV 60 of the imaging system 30 as shown at inset IV in FIG. 17B; and

(vii) determines a degree of similarity between the acquired image of the further second marker 754b and the virtual image 764 of the further second marker 754b, and responsive to determining that the degree of similarity between the acquired image of the further second marker 754b and the virtual image 764 of the further second marker 754b does not comply with a predetermined criterion, translates the virtual image 764 of the further second marker 754b in x and y with respect to the FOV 60 of the imaging system 30 until the degree of similarity between the acquired image of the further second marker 754b and the virtual image 764 of the further second marker 754b complies with the predetermined criterion.

The computing resource 40 determines the degree of similarity by evaluating a cross-correlation value between the acquired image of the further second marker 754b and the virtual image 764 of the further second marker 754b. The computing resource 40 determines that the degree of similarity complies with the predetermined criterion when the cross-correlation value has a maximum value.

The computing resource 40 then:

(vii) determines the position and orientation of the second marker 754a in the frame of reference of the motion control stage 20 based on:
(a) the measured relative position of the table 22 of the motion control stage 20 relative to the body 21 of the motion control stage 20 corresponding to the acquired image of the second marker 754a;
(b) the relative position of the virtual image 764 of the second marker 754a with respect to the FOV 60 of the imaging system 30 when the degree of similarity between the virtual image 764 of the second marker 754a and the acquired image of the second marker 754a complies with the predetermined criterion;
(c) the measured relative position of the table 22 of the motion control stage 20 relative to the body 21 of the motion control stage 20 corresponding to the acquired image of the further second marker 754b; and
(d) the relative position of the virtual image 764 of the further second marker 754b with respect to the FOV 60 of the imaging system 30 when the degree of similarity between the virtual image 764 of the further second marker 754b and the acquired image of the further second marker 754b complies with the predetermined criterion.

One of skill in the art will understand that the method of determining the position and orientation of the second marker 754a in the frame of reference of the motion control stage 20 described above with reference to FIG. 17B enables the orientation of the second marker 754a to be determined in the frame of reference of the motion control stage 20 with greater accuracy than the methods described with reference to FIGS. 3B, 5B, 11B and 13B.

The computing resource 40 then determines the position and orientation of the target area 708 in the frame of reference of the motion control stage 20 from the determined position and orientation of the second marker 754a in the frame of reference of the motion control stage 20 and the known position and orientation of the target area 708 relative to the second marker 754a.

The accuracy with which the position of the target area 708 is determined in the frame of reference of the motion control stage 20 depends on factors including the size of the features, the pixel density of the imaging system, and the wavelength of light used, but may be in a range from 1 μm to 1 nm. The accuracy with which the orientation of the target area 708 is determined in the frame of reference of the motion control stage 20 depends on the same factors and may be in the range 0.001-1 mrad.

The method for use in spatially registering first and second objects continues with the computing resource 40 determining the spatial relationship between the component 704 and the target area 708 in the frame of reference of the motion control stage 20 based on the determined position and orientation of the component 704 in the frame of reference of the motion control stage 20 and the determined position and orientation of the target area 708 in the frame of reference of the motion control stage 20.

In a variant of the further alternative method for use in spatially registering first and second objects described with reference to FIGS. 16, 17A and 17B, rather than the first substrate defining a first marker and a further first marker, the first object or component to be transferred may define the first marker and the further first marker.

The size of the PDMS stamp 37 of the pick and place tool 36 that engages any of the components 4, 104, 204, 304, 404, 504, 604, 704 may be larger or smaller than the component. A calibration step may be performed before the PDMS stamp 37 of the pick and place tool 36 engages any of the components to determine the spatial relationship between the PDMS stamp 37 of the pick and place tool 36 and the FOV 60 of the imaging system 30. The spatial relationship between the PDMS stamp 37 of the pick and place tool 36 and the FOV 60 of the imaging system 30 may be used to align the PDMS stamp 37 of the pick and place tool 36 with the centre of any of the components.

Rather than using the motion control stage to move the table 22 towards the PDMS stamp 37 of the pick and place tool 36 until one of the components 4, 104, 204, 304, 404, 504, 604, 704 engages the PDMS stamp 37 of the pick and place tool 36, the PDMS stamp 37 of the pick and place tool 36 may be movable towards one of the components 4, 104, 204, 304, 404, 504, 604, 704 until the PDMS stamp 37 of the pick and place tool 36 engages one of the components 4, 104, 204, 304, 404, 504, 604, 704. Similarly, rather than using the motion control stage to move the table 22 away from the PDMS stamp 37 of the pick and place tool 36, the PDMS stamp 37 of the pick and place tool 36 may be movable away from the table 22.

In the spatial registration methods described above with reference to FIGS. 1-17B the degree of similarity between an acquired image of an object such as a component or a marker and a virtual image of the object is determined by determining a cross-correlation value between the acquired image of the object and the virtual image of the object. Keypoint matching may be used prior to determining the cross-correlation value to determine an initial degree of similarity between the acquired image of the object and the virtual image of the object. Use of keypoint matching as a pre-cursor to determining a cross-correlation value in this way may improve the precision with which the degree of similarity between the acquired image of an object such as a component or a marker and the virtual image of the object is determined.

Furthermore, although the spatial registration methods described above with reference to FIGS. 1-17B determine that alignment between the acquired image of the object and the virtual image of the object is achieved when the cross-correlation value is maximised, other criteria may be used to determine when alignment between the acquired image of the object and the virtual image of the object is achieved. For example, the methods may include determining that alignment between the acquired image of the object and the virtual image of the object is achieved when the degree of similarity is greater than a predetermined threshold value. Alternative alignment determination criteria may be required for similarity matching algorithms other than evaluating the cross-correlation. Alternative alignment determination criteria may also be chosen to increase the speed of alignment and/or to improve at least one of the precision and reliability of alignment.

Although the spatial registration methods described above with reference to FIGS. 1-17B involve aligning and attaching a first object such as a component to a second object such as a second substrate using a differential adhesion method and/or capillary bonding, other methods of attaching the first object to the second object are possible. For example, the first object may be soldered to the second object.

Once detached from the first substrate or the table 22 of the motion control stage 20, the first object may be flipped before it is attached to the second object.

Although the spatial registration methods described above with reference to FIGS. 1-17B involve aligning a first object such as a component to a second object such as a second substrate, the first object may comprise a lithographic mask and the second object may comprise a work-piece e.g. a substrate or a wafer. The work-piece may comprise photoresist to be exposed to visible and/or UV light through the lithographic mask.

Any of the spatial registration methods described above with reference to FIGS. 1-17B may comprise compensating the determined spatial relationship between the target area and the component in the frame of reference of the motion control stage 20 for any misalignment between the z-axis of the motion control stage 20 and an optical axis of the imaging system 30, wherein the z-axis of the motion control stage 20 is normal to the upper surface 23 of the table 22 of the motion control stage 20.

Features of any one of the spatial registration methods described above with reference to FIGS. 1-17B may be combined with features of any one of the other spatial registration methods described above with reference to FIGS. 1-17B.

A method for use in the spatial registration of first and second objects may comprise spatially registering different first objects with the same second object.

A method for use in the spatial registration of first and second objects may comprise spatially registering different first objects to different target areas on the same second substrate.

A method for use in the spatial registration of first and second objects may comprise transferring different components defined on, or attached to, different first substrates to different target areas on the same second substrate.

A method for use in the spatial registration of first and second objects may comprise spatially registering different first objects with different second objects.

A method for use in the spatial registration of first and second objects may comprise spatially registering different first objects to different target areas on different second substrates.

A method for use in the spatial registration of first and second objects may comprise transferring different components defined on, or attached to, different first substrates to different target areas on different second substrates.

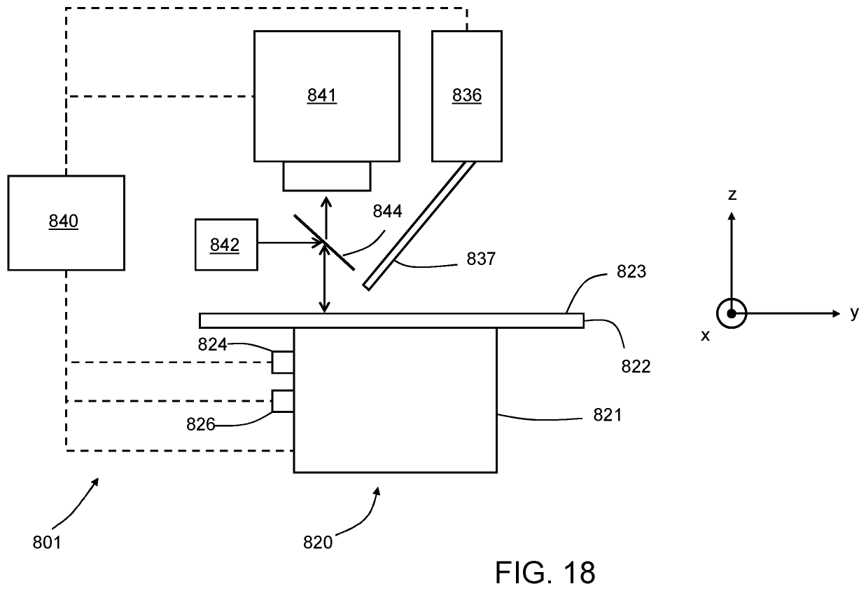

Referring now to FIG. 18, there is shown an alternative system generally designated 801 for use in spatially registering first and second objects (not shown in FIG. 18). The system 801 includes a motion control stage generally designated 820 having a base 821 and a table 822, wherein the table 822 is movable relative to the base 821.

As will be described in more detail below, in use, first and second objects (not shown in FIG. 18) have an unknown spatial relationship.

Although not shown explicitly in FIG. 18, one of ordinary skill in the art will understand that the motion control stage 820 includes one or more actuators for controlling the position and orientation of the table 822 relative to the base 821 within a frame of reference of the motion control stage 820 as indicated by the x, y and z directions illustrated in FIG. 18. The motion control stage 820 may also include one or more position sensors 824 for sensing relative x, y and z positions of the table 822 relative to the base 821 and one or more orientation sensors 826 for sensing a relative orientation or degree of rotation of the table 822 relative to the base 821 about the z-axis.

The system 801 further includes an optical power measurement system 841 mounted above the upper surface 823 of the table 822 of the motion control stage 820 for measuring the optical power at least a portion of light reflected from one or more objects located on the upper surface 823 of the table 822 of the motion control stage 820. The optical power measurement system 841 has a fixed spatial relationship relative to the base 821 of the motion control stage 820. The optical power measurement system 841 includes a single pixel detector (not shown) arranged so as to measure the optical power of at least a portion of light reflected from one or more objects located on the upper surface 823 of the table 822 of the motion control stage 820. The system 801 further includes a white light source 842 for illuminating one or more objects located on the upper surface 823 of the table 822 of the motion control stage 820 and a partially reflecting mirror arrangement 844 for reflecting at least some of the light from the white light source 842 so as to illuminate the one or more objects located on the upper surface 823 of the table 822 of the motion control stage 820 and so as to direct at least a portion of the incident light reflected from the one or more objects to the optical power measurement system 841.

The system 801 further includes a “pick-and-place” tool 836 mounted above the upper surface 823 of the table 822 of the motion control stage 820. The pick-and-place tool 836 includes a transparent pick-and-place head portion in the form of a PDMS stamp 837 for engaging and holding an object such as a component (not shown in FIG. 18). The PDMS stamp 837 is transparent to the light from the white light source 842. For example, the PDMS stamp 837 may include a transparent PDMS material mounted on a transparent substrate (e.g. glass). As will be described in more detail below, the tool 836 is configured to pick a first object, to hold the first object, and to release the first object once the first object is in engagement with a second object. The system 801 further includes a controller in the form of a computing resource 840. As indicated by the dashed lines in FIG. 18, the computing resource 840 is configured for communication with the one or more actuators (not shown), the one or more position sensors 824, the one or more orientation sensors 826, the optical power measurement system 841, and the tool 836.

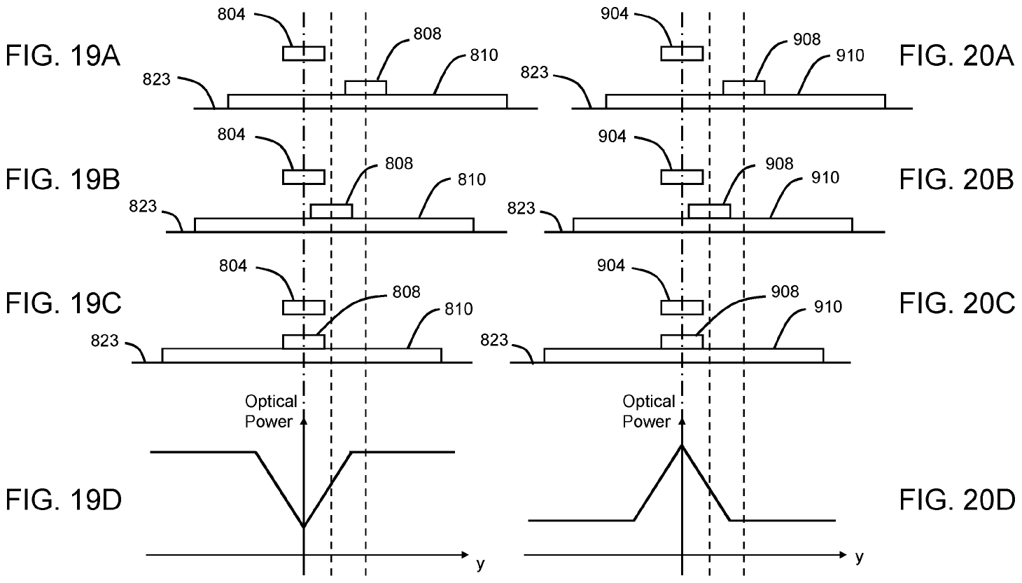

As will now be described with reference to FIGS. 19A-19D, the alternative system of FIG. 18 may be used for the spatial registration of a first object 804 and a second object 808. The second object 808 is attached or fixed with respect to a surface of a substrate or wafer 810. The substrate or wafer 810 is fixed to the upper surface 823 of the table 822 of the motion control stage 820. One or more regions of the surface of the substrate or wafer 810 adjacent to the second object 808 have a lower reflectivity than the second object 808. The first object 804 is located between the white light source 842 and the second object 808. The first object 804 and the substrate or wafer 810 are movable relative to one another.

The method includes directing light from the white light source 842 onto the first object 804, the second object 808, and the one or more regions of the surface of the substrate or wafer 810 adjacent to the second object 808 at the same time and using the optical power measurement system 841 to measure the optical power of at least a portion of the incident light that is reflected from the first and second objects 804, 808 and the one or more regions of the surface of the substrate or wafer 810 adjacent to the second object 808 while the first and second objects 804, 808 are aligned relative to one another. Specifically, the optical power measurement system 841 measures the optical power of at least a portion of the light that is reflected from the first and second objects 804, 808 and the one or more regions of the surface of the substrate or wafer 810 adjacent to the second object 808 while the PDMS stamp 837 of the tool 836 holds the first object 804 above the surface of the substrate or wafer 810 and the computing resource 840 controls the actuators of the motion control stage 820 so as to translate the table 822 of the motion control stage 820 (and therefore also the second object 808 and the substrate or wafer 810) in x-y relative to the base 821 of the motion control stage 820 and/or so as to rotate the table 822 of the motion control stage 820 (and therefore also the second object 808 and the substrate or wafer 810) about the z-axis relative to the base 821 of the motion control stage 820 until the measured optical power is minimised.

Alternatively, as will now be described with reference to FIGS. 20A-20D, the alternative system of FIG. 18 may be used for the spatial registration of a first object 904 and a second object 908. The second object 908 is attached or fixed with respect to a surface of a substrate or wafer 910. The substrate or wafer 910 is fixed to the upper surface 823 of the table 822 of the motion control stage 820. One or more regions of the surface of the substrate or wafer 910 adjacent to the second object 908 have a higher reflectivity than the second object 908. The first object 904 is located between the white light source 842 and the second object 908. The first object 904 and the substrate or wafer 910 are movable relative to one another.

The method includes directing light from the white light source 842 onto the first object 904, the second object 908, and the one or more regions of the surface of the substrate or wafer 910 adjacent to the second object 908 at the same time and using the optical power measurement system 841 to measure the optical power of at least a portion of the incident light that is reflected from the first and second objects 904, 908 and the one or more regions of the surface of the substrate or wafer 910 adjacent to the second object 908 while the first and second objects 904, 908 are aligned relative to one another. Specifically, the optical power measurement system 841 measures the optical power of at least a portion of the incident light that is reflected from the first and second objects 904, 908 and the one or more regions of the surface of the substrate or wafer 910 adjacent to the second object 908 while the PDMS stamp 837 of the tool 836 holds the first object 904 above the surface of the substrate or wafer 910 and the computing resource 840 controls the actuators of the motion control stage 820 so as to translate the table 822 of the motion control stage 820 (and therefore also the second object 908 and the substrate or wafer 910) in x-y relative to the base 821 of the motion control stage 820 and/or so as to rotate the table 822 of the motion control stage 820 (and therefore also the second object 908 and the substrate or wafer 910) about the z-axis relative to the base 821 of the motion control stage 820 until the measured optical power is maximised.

Such a method may enable the spatial registration of first and second objects to a resolution or accuracy of less than 1 μm, less than 100 nm, less than 10 nm, or of the order of 1 nm. Such a method may enable the spatial registration of the first and second objects where the first and second objects have a size or scale of less than 1 μm, less than 100 nm, less than 10 nm, or of the order of 1 nm.

One of ordinary skill in the art will understand that various modifications are possible to the apparatus and methods described above with reference to FIGS. 18, 19A-19D and 20A-20D. For example, the first object 804, 904 may comprise a first component such as an optical or an electronic component. The second object 808, 908 may comprise a second component such as an optical or an electronic component. Such a method may enable the spatial registration of components relative to one another.

The surface to which the second object 808, 908 is fixed or attached may be the upper surface 823 of the table 822 of the motion control stage 820.

The first component 804, 904 may be detachably attached to the table 822 of the motion control stage 820.

The first component 804, 904 may be detachably attached to a first substrate or wafer (not shown).

The second object 808, 908 may comprise a feature, a structure, a target area, a target region or a second component 808, 908 defined on a second substrate or wafer 810, 910, wherein the second substrate or wafer 810, 910 is fixed to the motion control stage 820.

Such a method may enable the alignment of a first component 808, 908 relative to a feature, a structure, a target area, a target region or a second component 808, 908 defined on a substrate or a wafer 810, 910.

The method may comprise using a multi-pixel detector to measure the total integrated optical power of at least a portion of the light that is reflected from the first and second objects 804 and 808 or 904 and 908 and the one or more regions of the surface of the substrate or wafer 810, 910 adjacent to the second object 808, 908 and that is incident across a plurality of the pixels of the multi-pixel detector.

The light may comprise light other than white light. For example, the light may comprise coherent light. The light may comprise visible or infrared light.

The method may comprise detaching the first object 804, 904 from the table 822 of the motion control stage 820.

The method may comprise detaching the first object 804, 904 from the first substrate (not shown).

The method may comprise holding the first object 804, 904.

The method may comprise moving the first object 804, 904 and the motion control stage 820 apart and holding the first object 804, 904 spaced apart from the motion control stage 820 and the second object 808, 908 to permit the motion control stage to move the second object 808, 908 relative to the first object 804, 904.

The method may comprise aligning the tool, head, stamp, probe or holder 836, 937 with respect to the first object 804, 904.

The method may comprise engaging the first object 804, 904 with the PDMS stamp 837.

The method may comprise using the PDMS stamp 837 to hold the first object 804, 904.

The method may comprise using the PDMS stamp 837 to detach the first object 804, 904 from the motion control stage 820.

The method may comprise moving the motion control stage 820 away from the first object 804, 904.

The method may comprise using the tool, head, stamp, probe or holder 836, to move the first object 804, 904 away from the motion control stage.

The method may comprise using the motion control stage 820 to move the second object 808, 908 relative to the first object 804, 904 so as to align the first and second objects 804 and 808 or 904 and 908 relative to one another until the measured optical power is maximised or minimised.

The method may comprise bringing the first and second objects 804 and 808 or 904 and 908 together until the first and second objects 804 and 808 or 904 and 908 are aligned and in engagement.

The method may comprise:

using the PDMS stamp 837 to hold the first object 804, 904 until the first and second objects 804 and 808 or 904 and 908 are aligned and in engagement; and then

using the PDMS stamp 837 to release the first object 804, 904 to permit attachment of the first and second objects 804 and 808 or 904 and 908.

The method may comprise using the motion control stage 820 to move the second object 808, 908 towards the first object 804, 904 until the first and second objects 804 and 808 or 904 and 908 are aligned and in engagement.

The method may comprise using the PDMS stamp 837 to move the first object 804, 904 towards the second object 808, 908 until the first and second objects 804 and 808 or 904 and 908 are aligned and in engagement.

As an alternative to, or in addition to, the PDMS stamp 837 of the tool, being transparent to the light used to illuminate the first object 804, 904 and the second object 808, 908, the head 837 of the tool 836 may be smaller than the first object 804, 904 to be picked. For example, the head 837 of the tool 836 may comprise a very fine tip or needle which is smaller than the first object 804, 904 to be picked.

The method may comprise attaching the first and second objects 804 and 808 or 904 and 908 while the first and second objects 804 and 808 or 904 and 908 are aligned.

Such a method may be used for the micro-assembly of the first and second objects 804 and 808 or 904 and 908, for example for transfer printing the first object 804, 904 onto the second object 808, 908.

Attaching the first and second objects 804 and 808 or 904 and 908 may comprise using a differential adhesion method and/or capillary bonding to attach the first and second objects 804 and 808 or 904 and 908 together.

Attaching the first and second objects 804 and 808 or 904 and 908 may comprise bonding the first and second objects or 904 and 908 using an intermediate adhesive material or agent such as an intermediate adhesion layer. Attaching the first and second objects 804 and 808 or 904 and 908 may comprise soldering the first and second objects 804 and 808 or 904 and 908.

The method may comprise flipping the first object 804, 904 over before attaching the first and second objects 804 and 808 or 904 and 908.

The first object 804, 904 may comprise a lithographic mask and the second object 808, 908 may comprise a work-piece e.g. a substrate or a wafer. The work-piece may comprise photoresist to be exposed to visible and/or UV light through the lithographic mask.

One of ordinary skill in the art will understand that one or more of the features of the embodiments of the present disclosure described above with reference to the drawings may produce effects or provide advantages when used in isolation from one or more of the other features of the embodiments of the present disclosure and that different combinations of the features are possible other than the specific combinations of the features of the embodiments of the present disclosure described above.

1. A method for use in the spatial registration of first and second objects, the method comprising:
fixing the first and second objects to the same motion control stage in an unknown spatial relationship;
using an imaging system to acquire an image of the first object or to acquire an image of a first marker provided with the first object, wherein the first marker and the first object have a known spatial relationship;
determining a position and orientation of the first object in a frame of reference of the motion control stage based at least in part on the acquired image of the first object or based at least in part on the acquired image of the first marker and the known spatial relationship between the first marker and the first object;
using the imaging system to acquire an image of the second object or to acquire an image of a second marker provided with the second object, wherein the second marker and the second object have a known spatial relationship; and
determining a position and orientation of the second object in the frame of reference of the motion control stage based at least in part on the acquired image of the second object or based at least in part on the acquired image of the second marker and the known spatial relationship between the second marker and the second object.

2. The method of claim 1, wherein the first marker is rotationally asymmetric and/or aperiodic in one or two dimensions, for example wherein the first marker comprises, or takes the form of, a grid which is rotationally asymmetric and/or aperiodic in one or two dimensions.

3. The method of claim 1, comprising:
determining the position and orientation of the first marker in the frame of reference of the motion control stage based at least in part on the acquired image of the first marker; and
using the determined position and orientation of the first marker in the frame of reference of the motion control stage and the known spatial relationship between the first marker and the first object to determine the position and orientation of the first object in the frame of reference of the motion control stage.

4. The method of claim 3, comprising:
(i) measuring a relative position and orientation of the motion control stage corresponding to the acquired image of the first marker;
(ii) determining a degree of similarity between the acquired image of the first marker and a virtual image of the first marker, which virtual image of the first marker has the same size and shape as the first marker, and
responsive to determining that the degree of similarity between the acquired image of the first marker and the virtual image of the first marker does not comply with a predetermined criterion, translating and/or rotating the virtual image of the first marker with respect to a FOV of the imaging system until the degree of similarity between the acquired image of the first marker and the virtual image of the first marker complies with the predetermined criterion; and
(iii) determining the position and orientation of the first marker in the frame of reference of the motion control stage based on the measured relative position and orientation of the motion control stage corresponding to the acquired image of the first marker and the relative position and orientation of the virtual image of the first marker with respect to the FOV of the imaging system when the degree of similarity between the virtual image of the first marker and the acquired image of the first marker complies with the predetermined criterion.

5. The method of claim 4, wherein determining the degree of similarity between the acquired image of the first marker and the virtual image of the first marker comprises evaluating a cross-correlation value between the acquired image of the first marker and the virtual image of the first marker and wherein the degree of similarity between the acquired image of the first marker and the virtual image of the first marker complies with the predetermined criterion when the cross-correlation value is greater than a predetermined threshold value or has a maximum value.

6. The method of claim 3, comprising:
(i) measuring a relative position and orientation of the motion control stage corresponding to the acquired image of the first marker;
(ii) determining a degree of similarity between the acquired image of the first marker and a virtual image of the first marker, which virtual image of the first marker has the same size and shape as the first marker, and responsive to determining that the degree of similarity between the acquired image of the first marker and the virtual image of the first marker does not comply with a predetermined criterion, translating the virtual image of the first marker with respect to a FOV of the imaging system until the degree of similarity between the acquired image of the first marker and the virtual image of the first marker complies with the predetermined criterion;
(iii) translating the motion control stage along a linear translation axis of the motion control stage by a distance equal to a known separation between the first marker and a further first marker which is also provided with the first object so that the further first marker is in the FOV of the imaging system;
(iv) using the imaging system to acquire an image of the further first marker;
(v) measuring a relative position and orientation of the motion control stage corresponding to an acquired image of the further first marker;
(vi) determining a degree of similarity between the acquired image of the further first marker and a virtual image of the further first marker, which virtual image of the further first marker has the same size and shape as the further first marker, and translating the virtual image of the further first marker with respect to the FOV of the imaging system until the degree of similarity between the acquired image of the further first marker and the virtual image of the further first marker complies with a predetermined criterion; and
(vii) determining the position and orientation of the first marker in the frame of reference of the motion control stage based on:
(a) the measured relative position of the motion control stage corresponding to the acquired image of the first marker;
(b) the relative position of the virtual image of the first marker with respect to the FOV of the imaging system when the degree of similarity between the virtual image of the first marker and the acquired image of the first marker complies with the predetermined criterion;
(c) the measured relative position of the motion control stage corresponding to the acquired image of the further first marker; and
(d) the relative position of the virtual image of the further first marker with respect to the FOV of the imaging system when the degree of similarity between the virtual image of the further first marker and the acquired image of the further first marker complies with the predetermined criterion.

7. The method of claim 6,
wherein determining the degree of similarity between the acquired image of the first marker and the virtual image of the first marker comprises evaluating a cross-correlation value between the acquired image of the first marker and the virtual image of the first marker and wherein the degree of similarity between the acquired image of the first marker and the virtual image of the first marker complies with the predetermined criterion when the cross-correlation value is greater than a predetermined threshold value or has a maximum value; and
wherein determining the degree of similarity between the acquired image of the further first marker and the virtual image of the further first marker comprises evaluating a cross-correlation value between the acquired image of the further first marker and the virtual image of the further first marker and wherein the degree of similarity between the acquired image of the further first marker and the virtual image of the further first marker complies with the predetermined criterion when the cross-correlation value is greater than a predetermined threshold value or has a maximum value.

8. The method of claim 1, wherein the second marker is rotationally asymmetric and/or aperiodic in one or two dimensions, for example wherein the second marker comprises, or takes the form of, a grid which is rotationally asymmetric and/or aperiodic in one or two dimensions.

9. The method of claim 1, comprising:
determining the position and orientation of the second marker in the frame of reference of the motion control stage based at least in part on the acquired image of the second marker; and
using the determined position and orientation of the second marker in the frame of reference of the motion control stage and the known spatial relationship between the second marker and the second object to determine the position and orientation of the second object in the frame of reference of the motion control stage.

10. The method of claim 9, comprising:
(i) measuring a relative position and orientation of the motion control stage corresponding to the acquired image of the second marker;
(ii) determining a degree of similarity between the acquired image of the second marker and a virtual image of the second marker, which virtual image of the second marker has the same size and shape as the second marker, and responsive to determining that the degree of similarity between the acquired image of the second marker and the virtual image of the second marker does not comply with a predetermined criterion, translating and/or rotating the virtual image of the second marker with respect to the FOV of the imaging system until the degree of similarity between the acquired image of the second marker and the virtual image of the second marker complies with the predetermined criterion; and
(iii) determining the position and orientation of the second marker in the frame of reference of the motion control stage based on the measured relative position and orientation of the motion control stage corresponding to the acquired image of the second marker and the relative position and orientation of the virtual image of the second marker with respect to the FOV of the imaging system when the degree of similarity between the virtual image of the second marker and the acquired image of the second marker complies with the predetermined criterion.

11. The method of claim 10, wherein determining the degree of similarity between the acquired image of the second marker and the virtual image of the second marker comprises evaluating a cross-correlation value between the acquired image of the second marker and the virtual image of the second marker and wherein the degree of similarity between the acquired image of the second marker and the virtual image of the second marker complies with the predetermined criterion when the cross-correlation value is greater than a predetermined threshold value or has a maximum value.

12. The method of claim 9, comprising:
(i) measuring a relative position and orientation of the motion control stage corresponding to the acquired image of the second marker;
(ii) determining a degree of similarity between the acquired image of the second marker and a virtual image of the second marker, which virtual image of the second marker has the same size and shape as the second marker, and responsive to determining that the degree of similarity between the acquired image of the second marker and the virtual image of the second marker does not comply with a predetermined criterion, translating the virtual image of the second marker with respect to a FOV of the imaging system until the degree of similarity between the acquired image of the second marker and the virtual image of the second marker complies with the predetermined criterion;
(iii) translating the motion control stage along a linear translation axis of the motion control stage by a distance equal to a known separation between the second marker and a further second marker which is also provided with the second object so that the further second marker is in the FOV of the imaging system;
(iv) using the imaging system to acquire an image of the further second marker;
(v) measuring a relative position and orientation of the motion control stage corresponding to an acquired image of the further second marker;
(vi) determining a degree of similarity between the acquired image of the further second marker and a virtual image of the further second marker, which virtual image of the further second marker has the same size and shape as the further second marker, and translating the virtual image of the further second marker with respect to the FOV of the imaging system until the degree of similarity between the acquired image of the further second marker and the virtual image of the further second marker complies with a predetermined criterion; and
(vii) determining the position and orientation of the second marker in the frame of reference of the motion control stage based on:
(a) the measured relative position of the motion control stage corresponding to the acquired image of the second marker;
(b) the relative position of the virtual image of the second marker with respect to the FOV of the imaging system when the degree of similarity between the virtual image of the second marker and the acquired image of the second marker complies with the predetermined criterion;
(c) the measured relative position of the motion control stage corresponding to the acquired image of the further second marker; and
(d) the relative position of the virtual image of the further second marker with respect to the FOV of the imaging system when the degree of similarity between the virtual image of the further second marker and the acquired image of the further second marker complies with the predetermined criterion.

13. The method of claim 12,
wherein determining the degree of similarity between the acquired image of the second marker and the virtual image of the second marker comprises evaluating a cross-correlation value between the acquired image of the second marker and the virtual image of the second marker and wherein the degree of similarity between the acquired image of the second marker and the virtual image of the second marker complies with the predetermined criterion when the cross-correlation value is greater than a predetermined threshold value or has a maximum value; and
wherein determining the degree of similarity between the acquired image of the further second marker and the virtual image of the further second marker comprises evaluating a cross-correlation value between the acquired image of the further second marker and the virtual image of the further second marker and wherein the degree of similarity between the acquired image of the further second marker and the virtual image of the further second marker complies with the predetermined criterion when the cross-correlation value is greater than a predetermined threshold value or has a maximum value.

14. The method of claim 1, comprising:
(i) measuring a relative position and orientation of the motion control stage corresponding to an acquired image of the first object;
(ii) determining a degree of similarity between the acquired image of the first object and a virtual image of the first object, which virtual image of the first object has the same size and shape as the first object, and responsive to determining that the degree of similarity between the acquired image of the first object and the virtual image of the first object does not comply with a predetermined criterion, translating and/or rotating the virtual image of the first object with respect to a FOV of the imaging system until the degree of similarity between the acquired image of the first object and the virtual image of the first object complies with the predetermined criterion; and
(iii) determining the position and orientation of the first object in the frame of reference of the motion control stage based on the measured relative position and orientation of the motion control stage corresponding to the acquired image of the first object and the relative position and orientation of the virtual image of the first object with respect to the FOV of the imaging system when the degree of similarity between the virtual image of the first object and the acquired image of the first object complies with the predetermined criterion.

15. The method of claim 14, wherein determining the degree of similarity between the acquired image of the first object and the virtual image of the first object comprises evaluating a cross-correlation value between the acquired image of the first object and the virtual image of the first object and wherein the degree of similarity between the acquired image of the first object and the virtual image of the first object complies with the predetermined criterion when the cross-correlation value is greater than a predetermined threshold value or has a maximum value.

16. The method of claim 1, comprising:
(i) measuring a relative position and orientation of the motion control stage corresponding to an acquired image of the second object;
(ii) determining a degree of similarity between the acquired image of the second object and a virtual image of the second object, which virtual image of the second object has the same size and shape as the second object and responsive to determining that the degree of similarity between the acquired image of the second object and the virtual image of the second object does not comply with a predetermined criterion, translating and/or rotating the virtual image of the second object with respect to the FOV of the imaging system until the degree of similarity between the acquired image of the second object and the virtual image of the second object complies with the predetermined criterion; and
(iii) determining the position and orientation of the second object in the frame of reference of the motion control stage based on the measured relative position and orientation of the motion control stage corresponding to the acquired image of the second object and the relative position and orientation of the virtual image of the second object with respect to the FOV of the imaging system when the degree of similarity between the virtual image of the second object and the acquired image of the second object complies with the predetermined criterion.

17. The method of claim 16, wherein determining the degree of similarity between the acquired image of the second object and the virtual image of the second object comprises evaluating a cross-correlation value between the acquired image of the second object and the virtual image of the second object and wherein the degree of similarity between the acquired image of the second object and the virtual image of the second object complies with the predetermined criterion when the cross-correlation value is greater than a predetermined threshold value or has a maximum value.

18. The method of any preceding claim 1, wherein the first object is detachably attached to the motion control stage or wherein the first object is detachably attached to a first substrate or wafer and the first substrate or wafer is fixed to the motion control stage.

19. The method of any preceding claim 1, wherein the second object is detachably attached to the motion control stage or wherein the second object comprises a feature, a structure, a target area, a target region defined on a second substrate or wafer, and the second substrate or wafer is fixed to the motion control stage.

20. The method of any preceding claim 1, comprising determining a spatial relationship between the first and second objects in the frame of reference of the motion control stage based on the determined position and orientation of the first object in the frame of reference of the motion control stage and the determined position and orientation of the second object in the frame of reference of the motion control stage.

21. The method of claim 20, comprising spatially registering the first and second objects based on the determined spatial relationship between the first and second objects in the frame of reference of the motion control stage, for example by holding the first object, moving the first object and the motion control stage apart, using the motion control stage to move the second object relative to the first object based on the determined spatial relationship between the first and second objects in the frame of reference of the motion control stage until the first and second objects are in alignment, and then bringing the first and second objects together until the first and second objects are aligned and in engagement.

22. A method for use in the spatial registration of first and second objects, the second object being fixed or attached to a surface and the surface having one or more regions adjacent to the second object, which surface regions have a different reflectivity to the second object, and the method comprising:
locating the first object between a light source and the second object;
directing light from the light source onto the first object, the second object, and one or more of the surface regions of the surface adjacent to the second object;
using single-pixel detection to measure the optical power of at least a portion of the light that is reflected from the first and second objects and the one or more surface regions adjacent to the second object while the first and second objects are aligned relative to one another; and
aligning the first and second objects relative to one another until the measured optical power is maximised or minimised.

23. The method of claim 22, wherein using single-pixel detection to measure the optical power of at least a portion of the light that is reflected from the first and second objects and the one or more surface regions adjacent to the second object comprises:
using a single-pixel detector to measure the optical power of at least a portion of the light that is reflected from the first and second objects and the one or more surface regions adjacent to the second object; or
using a multi-pixel detector to measure the total integrated optical power of at least a portion of the light that is reflected from the first and second objects and the one or more surface regions adjacent to the second object and that is incident across a plurality of the pixels of the multi-pixel detector.

24. The method of claim 22, wherein the first object is detachably attached to the motion control stage or the first object is detachably attached to a first substrate or wafer, and the first substrate or wafer is fixed to the motion control stage.

25. The method of claim 22, wherein the surface to which the second object is fixed or attached is a surface of a motion control stage or a surface of a second substrate or wafer.

26. The method of claim 22, comprising holding the first object, moving the first object and the motion control stage apart, using the motion control stage to move the second object relative to the first object so as to align the first and second objects relative to one another until the measured optical power is maximised or minimised, and then bringing the first and second objects together until the first and second objects are aligned and in engagement.

27. The method of claim 21, comprising attaching the first and second objects while the first and second objects are aligned, for example using at least one of a differential adhesion method, a capillary bonding method, or a soldering method, or by bonding the first and second objects together using an intermediate adhesive material or agent such as an intermediate adhesion layer, to attach the first and second objects while the first and second objects are aligned.

28. The method of claim 1, wherein at least one of the first and second objects comprises a component such as an optical component or an electronic component or wherein at least one of the first and second objects comprises a portion, piece or chip of material.

29. The method of claim 1, wherein one of the first and second objects comprises a lithographic mask and the other of the first and second objects comprises a work-piece such as a substrate or a wafer.

30. The method of claim 26, comprising attaching the first and second objects while the first and second objects are aligned, for example using at least one of a differential adhesion method, a capillary bonding method, or a soldering method, or by bonding the first and second objects together using an intermediate adhesive material or agent such as an intermediate adhesion layer, to attach the first and second objects while the first and second objects are aligned.

31. The method of claim 22, wherein at least one of the first and second objects comprises a component such as an optical component or an electronic component or wherein at least one of the first and second objects comprises a portion, piece or chip of material.

32. The method of claim 22, wherein one of the first and second objects comprises a lithographic mask and the other of the first and second objects comprises a work-piece such as a substrate or a wafer.
